(19) United States
(12) Patent Application Publication
(10) Pub. No.: US 2002/0127776 A1
(43) Pub. Date: Sep. 12, 2002

(54) Semiconductor device having an organic material layer and method for making the same

(75) Inventors: Shinsuke Nakajo, Nakakoma (JP); Norio Fukasawa, Kawasaki (JP); Takashi Hozumi, Kasugai (JP); Shinya Nakaseko, Kawasaki (JP)

Correspondence Address: ARMSTRONG,WESTERMAN & HATTORI, LLP, 1725 K STREET, NW., SUITE 1000, WASHINGTON, DC, 20006, US

(73) Assignee: Fujitsu Limited, Kawasaki (JP)

(21) Appl. No.: 09/969,783

(22) Filed: Oct. 4, 2001

(30) Foreign Application Priority Data
Mar. 12, 2001 (JP) 2001-068783

(51) Int. Cl. H01L 23/28; H01L 23/495; H01L 23/48; H01L 21/44; H01L 21/48; H01L 21/50; H01L 23/29

(52) U.S. Cl. 438/110; 257/788; 257/787; 257/666; 257/696; 438/114

(57) ABSTRACT

A semiconductor device includes a semiconductor element having a circuit surface on which a projection electrode is formed, a seal resin which seals the circuit surface of the semiconductor element while exposing at least an end part of the projection electrode, a connect surface that is to face a board when the semiconductor device is implemented on the board, a back surface which is opposite to the connect surface, a side surface arranged between the connect surface and the back surface, and an organic material layer formed on the side surface.

### BACKGROUND OF THE INVENTION

1. Field of the Invention

The present invention generally relates to semiconductor devices and methods for making the same, and more particularly, to a semiconductor device having a chip size package structure in which a mold resin is arranged on a semiconductor chip and a method for making the same.

2. Description of the Related Art

Recently, it has been attempted to miniaturize semiconductor devices and achieve a high circuit density on the basis of a demand for miniaturizing electronic apparatus and devices. Semiconductor device using wires thus have a tendency that wire pitches become narrower. A semiconductor device having a chip size package structure, in which a miniaturization of the semiconductor device is attempted by making a form of the semiconductor device similar to that of a semiconductor chip, has also been proposed.

Against this background, there is a demand for a semiconductor device which can keep high reliance even if it is attempted to miniaturize semiconductor devices and achieve a high circuit density.

FIG. 1 is a view showing an example of a conventional semiconductor device 1A. FIG. 2 is a view showing an example of a conventional semiconductor device 1B.

Referring to FIG. 1, the semiconductor device 1A has a multi-chip package (MCP) structure in which a plurality of semiconductor elements 2A and 2B are arranged. The semiconductor element 2A is arranged on an upper surface of a multi-layer interconnection board 3A. The semiconductor element 2B is arranged on an upper surface of a multi-layer interconnection board 3B. The multi-layer interconnection board 3A is fixed on a base board 4. The multi-layer interconnection board 3B is fixed on the multi-layer interconnection board 3A. That is, the multi-layer interconnection board 3B is configured to be stuck on the multi-layer interconnection board 3A.

The semiconductor element 2A is connected with a wire 7 formed on the multi-layer interconnection board 3A. Similarly, the semiconductor element 2B is connected with a wire 7 formed on the multi-layer interconnection board 3B. Solder balls 6 are arranged beneath the base board 4, as an external connection terminal.

The wires 7 formed on the multi-layer interconnection board 3A and the wires 7 formed on the multi-layer interconnection board 3B are connected electronically by wires 8. The wires 7 formed on the multi-layer interconnection board 3A and an upper part electrode 9A on the base board 4 are connected electronically by wires 8. Also, the upper part electrode 9A on the base board 4 and a lower part electrode 9B on which the solder ball 6 is arranged are connected by a through hole 9C. Thus, the semiconductor elements 2A and 2B are respectively connected to the solder ball 6.

Referring to FIG. 2-(A), a semiconductor device 1B is of a so-called chip size package (CSP) type. The semiconductor device 1B includes a semiconductor element 2, a seal resin 10, and solder balls 15. The semiconductor element 2 has a plurality of projection electrodes 11 formed on a circuit surface 14. The projection electrode 11 is connected with an electrode 12 of the semiconductor element 2 by a wire 13.

The seal resin 10 is arranged on the circuit surface 14 where the projection electrode 11 of the semiconductor element 2 is formed. An end part of the projection electrode 11 is exposed from a surface of the seal resin 10 which is formed as mentioned above. The solder ball 15 is arranged on the portion of the projection electrode 11 that is exposed from the seal resin 10.

As to the semiconductor device 1A shown in FIG. 1, as the number of terminals is increased on the basis of that the semiconductor elements 2A and 2B achieve a high circuit density, the number of the wires 8 is also increased. It is preferable that a wire loop of the wire 8 is small in order to miniaturize the semiconductor device 1A.

If an attempt is made to miniaturize the semiconductor device 1A and achieve a high circuit density, it gives rise to problems. For instance, the wire 8 and the multi-layer interconnection board 3B may interfere each other, and, also, the neighboring wires 8 may come in contact and short-circuit during a seal process of the seal resin 5, at a place shown by an arrow A in FIG. 1. These disadvantages cause a decline of the reliance of the semiconductor device 1A.

As shown in FIG. 2, a back surface 2a and a side surface 2b of the semiconductor element 2 are exposed in the semiconductor device 1B. Because of this, the semiconductor device 1B may suffer chipping, cracking or the like, as shown in FIG. 2(B), at the time of dicing a semiconductor substrate (wafer) into pieces of semiconductor devices or at the time of handling the semiconductor device 1B. This disadvantage causes a decline of the reliance of the semiconductor device 1B.

Furthermore, the semiconductor device 1B shown in FIG. 2 is generally tested before dicing of the wafer while it is part of the semiconductor substrate. FIG. 3 shows the way the semiconductor substrate 16 is tested by using a probe pin 18.

There is a difference between a semiconductor substrate 16 made of a semiconductor material such as a silicon and a seal resin 10 made of an organic resin, with respect to thermal expansion coefficients. Due to the difference of thermal expansion coefficients, warping occurs as to the semiconductor substrate 16 as shown in FIG. 3.

Therefore, when the semiconductor substrate 16 is mounted on a stage 17 for test, outer edges of the semiconductor substrate 16 is elevated from the stage 17 by Ah as shown in FIG. 3. Thus, it is difficult to bring the probe pins 18 in contact with all of the projection electrodes 11 properly. Accordingly, there is a disadvantage that it is impossible to conduct a test with a high reliance.

### SUMMARY OF THE INVENTION

Accordingly, it is a general object of the present invention is to provide a novel and useful semiconductor device and a method for making the same in which one or more of the problems described above are eliminated.

Another and more specific object of the present invention is to provide a semiconductor device keeping a high reliance even if an attempt is made to miniaturize the semiconductor device and achieve a high circuit density as to the semiconductor device and a method for making the same.

The above object of the present invention is achieved by a semiconductor device including a semiconductor element having a circuit surface on which a projection electrode is formed, a seal resin which seals the circuit surface of the semiconductor element while exposing at least an end part of the projection electrode, a connect surface that is to face a board when the semiconductor device is implemented on the board, a back surface which is opposite to the connect surface, a side surface situated between the connect surface and the back surface, and an organic material layer formed on the side surface.

According to the invention, the organic material layer is formed on a side surface of the semiconductor element. Therefore, the organic material layer plays a role of a support member for the semiconductor device. Accordingly, chipping or cracking is prevented from occurring on the semiconductor element at the time of handling the semiconductor device.

Other object of the present invention is to provide a method of manufacturing a semiconductor device, including an element forming step of forming a plurality of semiconductor elements on a surface of a semiconductor substrate and forming a projection electrode on the semiconductor elements, a sealing step of sealing the surface of the semiconductor element with a seal resin while exposing at least an end part of the projection electrode, a cutting step of cutting the semiconductor substrate into the respective semiconductor elements, each of which constitutes a semiconductor element body, and a film forming step of forming a film of an organic material in a vapor phase on the semiconductor element body after the cutting process is completed, thereby forming an organic material layer.

According to the invention, it is possible to form the organic material layer by forming a film of the organic material in the vapor phase. Therefore, it is possible to form the organic material layer by applying the vapor phase growth apparatus for forming the circuit. Hence, it can be attempted to keep a manufacturing cost as compared with a mold method in which the mold is used for forming.

Other object of the present invention is to provide a semiconductor device including a semiconductor element having a circuit surface on which a projection electrode is formed, a seal resin which seals the circuit surface of the semiconductor element while exposing at least an end part of the projection electrode, a connect surface that is to face a board when the semiconductor device is implemented on the board, a back surface which is opposite to the connect surface, a side surface arranged between the connect surface and the back surface, and an organic material layer formed on at least one surface of the connect surface and the back surface except the side surface.

According to the invention, the organic material layer is formed on at least either the connect surface or the back surface. Therefore, warping is prevented from occurring on the semiconductor element, and chipping or cracking is prevented from occurring on the semiconductor element at the time of handling the semiconductor device.

Other object of the present invention is to provide a method of manufacturing a semiconductor device including an element forming step of forming a plurality of semiconductor elements on a surface of a semiconductor substrate and forming a projection electrode on the semiconductor elements, a sealing step of sealing the surface of the semiconductor element with a seal resin while exposing at least an end part of the projection electrode, a film forming step of forming a film of an organic material in a vapor phase on the semiconductor element body thereby forming an organic material layer, and a cutting step of cutting the semiconductor substrate into the respective semiconductor element after the film forming step is completed, each of which constitutes a semiconductor element body.

According to the invention, the organic material layer is formed on a side of the semiconductor element. Therefore, the organic material layer plays a role of a support member for the semiconductor device. Accordingly, chipping or cracking is prevented from occurring on the semiconductor element at the time of handling the semiconductor device.

Also, it is possible to form the organic material layer by forming a film of the organic material in the vapor phase. Therefore, it is possible to form the organic material layer by applying the vapor phase growth apparatus for forming the circuit on the semiconductor substrate. Hence, it can be attempted to keep a manufacturing cost as compared with a mold method in which the mold is used for forming. Furthermore, it is possible to form the organic material layer with a constant film thickness regardless of the size of the semiconductor substrate.

Other object of the present invention is to provide a semiconductor device having a semiconductor element including a connect surface on which a projection electrode is formed and which is to face a board when the semiconductor device is implemented on the board, a back surface which is opposite to the connect surface, a side surface situated between the connect surface and the back surface, and an organic material layer formed on at least a part of the connect surface except an end part of the projection electrode.

According to the invention, the organic material layer plays a role of the seal resin. Therefore, the seal resin is not needed, so that it is possible to attempt to reduce the coast of the semiconductor device. Also, the organic material layer is formed on the connect side. Therefore, warping is prevented from occurring on the semiconductor element. The organic material layer may be formed on the side surface and/or the back surface of the semiconductor device. With the above-mentioned structure, chipping or cracking is prevented from occurring on the semiconductor element at the time of handling the semiconductor device.

Other object of the present invention is to provide a method of manufacturing a semiconductor device including an element forming step of forming a plurality of semiconductor elements on a surface of a semiconductor substrate and forming a projection electrode on the semiconductor elements, a cutting step of cutting the semiconductor substrate into the respective semiconductor elements, each of which constitutes a semiconductor element body, and a film forming step of forming a film of an organic material in a vapor phase on the semiconductor element body after the cutting process is completed, thereby forming an organic material layer.

According to the invention, it is possible to simplify the manufacturing process for the semiconductor device because the process for forming the seal resin is not needed. Also, the mold for forming the seal resin is not necessary, so that it is possible to attempt to reduce the cost of the semiconductor device. Furthermore, the organic material layer is formed by forming a film of the organic material in the vapor. Therefore, it is possible to form the organic material layer by applying the vapor phase growth apparatus for forming the circuit on the semiconductor substrate. Hence, it can be attempted to keep a manufacturing cost.

Also, it is possible to form the organic material layer on the side surface of the semiconductor element by carrying out the film forming process after the cutting step is completed. Furthermore, because the organic material is piled and formed in the vapor, it is possible to form the organic material layer with a constant film thickness regardless of the size of the semiconductor substrate.

Other object of the present invention is to provide a method for manufacturing a semiconductor device including an element forming step of forming a plurality of semiconductor elements on a circuit surface of a semiconductor substrate and forming a projection electrode on the semiconductor elements, a film forming step of forming a film of an organic material in a vapor phase on the semiconductor element body thereby forming an organic material layer on at least a back surface situated at opposite side surface to the circuit surface of the semiconductor substrate, an element cutting step of remaining the organic material layer and cutting the semiconductor substrate into the respective semiconductor elements after the film forming step is completed, a test step of conducting a test as to the semiconductor element after the element cutting step is completed, and an organic material layer cutting step of cutting the organic material layer into respective semiconductor elements after the test process is completed.

According to the invention, it is possible to simplify the manufacturing process for the semiconductor device because the process for forming the seal resin is not needed. Also, the mold for forming the seal resin is not necessary, so that it is possible to attempt to reduce the cost of the semiconductor device. Furthermore, the organic material layer is formed by forming a film of the organic material in the vapor. Therefore, it is possible to form the organic material layer by applying the vapor phase growth apparatus for forming the circuit on the semiconductor substrate. Hence, it can be attempted to keep a manufacturing cost.

Also, it is possible to form the organic material layer on the side surface of the semiconductor element. Furthermore, because a film of the organic material is formed in the vapor, it is possible to form the organic material layer with a constant film thickness regardless of the size of the semiconductor substrate.

Other object of the present invention is to provide a method of manufacturing a semiconductor device including an element forming step of forming a plurality of semiconductor elements on a circuit surface of a semiconductor substrate and forming a projection electrode on the semiconductor elements, a film forming step of forming a film of an organic material in a vapor phase on the semiconductor element body thereby forming an organic material layer on at least a back surface situated at opposite side surface to the circuit surface of the semiconductor substrate, an element cutting step of remaining the organic material layer and cutting the semiconductor substrate into the respective semiconductor elements after the film forming step is completed, a test step of conducting a test as to the semiconductor element after the element cutting step is completed; and an organic material layer cutting step of cutting the organic material layer into respective semiconductor elements after the test process is completed.

According to the invention, the organic material layer cut process is carried out after the test step for the semiconductor substrate is completed, in order to cut the semiconductor substrate into respective semiconductor devices. Therefore, it is possible to conduct a test regarding the cut semiconductor element in the test step. Thus, it is possible to have no effect of warping occurring on the semiconductor substrate in a not-cut process. Therefore, it is possible to conduct the test reliably. Also, the cut semiconductor element is connected with the organic material layer. Therefore, the respective semiconductor element keeps a state in which it is positioned by the organic material layer. Hence, it is possible to position the test tool such as the probe pin and the semiconductor element easily. Therefore, it is possible to conduct the test reliably.

Other object of the present invention is to provide a semiconductor device including a semiconductor element, an interposer including a wire and connecting the semiconductor device with an external connection terminal, a seal resin for sealing at least the semiconductor element and an organic material layer that covers at least the wire. Also, other object of the present invention is to provide a method of manufacturing a semiconductor device including a wire connecting step of connecting a semiconductor element and an interposer with a wire, a sealing step of sealing at least the semiconductor element and the wire by a seal resin, and a film forming step of forming a film of an organic material in a vapor on at least the wire, after the wire connecting step is carried out and before the sealing step is carried out, thereby an forming an organic material layer.

According to the inventions, the sealing step is carried out after the organic material layer is formed on at least the wire, by the film forming step after the wire connecting step is carried out. Therefore, even if the wire is displaced due to the resin insulted in the seal process and the neighboring wires are contacted each other, the wires are not short-circuit because the wires are covered with the insulating organic material layer. Hence, even if the wire density is high, the reliance of the semiconductor device can keep high.

Other objects, features, and advantages of the present invention will be more apparent from the following detailed description when read in conjunction with the accompanying drawings.

### BRIEF DESCRIPTION OF THE DRAWINGS

FIG. 1 is a view showing an example of a conventional semiconductor device;

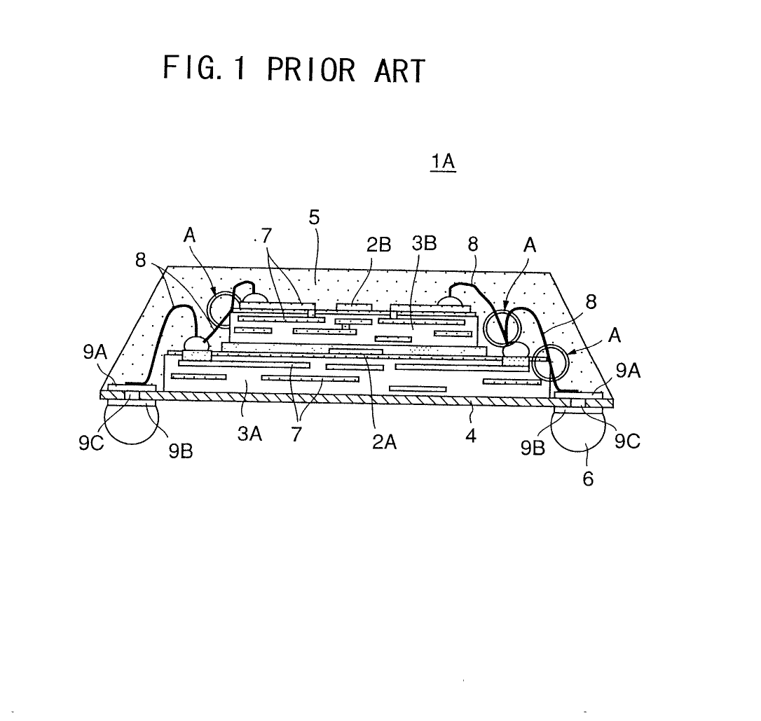

FIG. 2 is a view showing another example of a conventional semiconductor device;

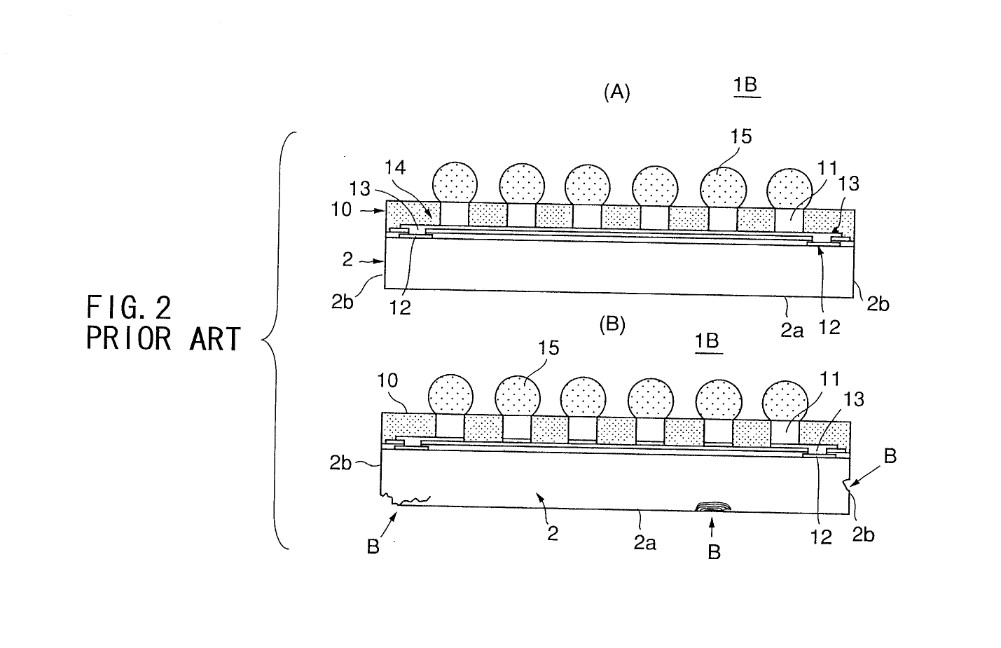

FIG. 3 is a view explaining disadvantages as to a method for manufacturing of a conventional semiconductor device;

FIG. 4 is a view showing a semiconductor device according to the first embodiment of the present invention;

FIG. 5 is a view explaining a method for manufacturing of a semiconductor device according to the first embodiment of the present invention;

FIG. 6 is a view explaining a method for forming an organic material layer;

FIG. 7 is a view showing a semiconductor device according to the second embodiment of the present invention;

FIG. 8 is a view explaining a method for manufacturing of a semiconductor device according to the second embodiment of the present invention;

FIG. 9 is a view showing a semiconductor device according to the third embodiment of the present invention;

FIG. 10 is a view explaining a method for manufacturing of a semiconductor device according to the third embodiment of the present invention;

FIG. 11 is a view showing a semiconductor device according to the fourth embodiment of the present invention;

FIG. 12 is a view explaining a method for manufacturing of a semiconductor device according to the fourth embodiment of the present invention;

FIG. 13 is a view explaining another method for manufacturing of a semiconductor device according to the fourth embodiment of the present invention;

FIG. 14 is a view showing a semiconductor device according to the fifth embodiment of the present invention;

FIG. 15 is a view explaining a method for manufacturing of a semiconductor device according to the fifth embodiment of the present invention;

FIG. 16 is a view showing a semiconductor device according to the sixth embodiment of the present invention;

FIG. 17 is a view explaining a method for manufacturing of a semiconductor device according to the sixth embodiment of the present invention;

FIG. 18 is a view showing a semiconductor device according to the seventh embodiment of the present invention;

FIG. 19 is a view explaining a method for manufacturing of a semiconductor device according to the seventh embodiment of the present invention;

FIG. 20 is a view showing a semiconductor device according to the eighth embodiment of the present invention;

FIG. 21 is a view explaining a method for manufacturing of a semiconductor device according to the eighth embodiment of the present invention;

FIG. 22 is an enlarged view showing a projection electrode of the semiconductor device according to the sixth embodiment of the present invention;

FIG. 23 is a view showing a semiconductor device according to the ninth embodiment of the present invention;

FIG. 24 is a view explaining a method for manufacturing of a semiconductor device according to the ninth embodiment of the present invention;

FIG. 25 is a view showing a semiconductor device according to the tenth embodiment of the present invention;

FIG. 26 is a view explaining a method for manufacturing of a semiconductor device according to the tenth embodiment of the present invention;

FIG. 27 is a view explaining a mount part formed on a chamfer part;

FIG. 28 is another view explaining a mount part formed on a chamfer part;

FIG. 29 is a view explaining the first deformed example of the method for manufacturing of a semiconductor device according to the tenth embodiment of the present invention;

FIG. 30 is a view explaining the second deformed example of the method for manufacturing of a semiconductor device according to the tenth embodiment of the present invention;

FIG. 31 is a view explaining a semiconductor device and a method for manufacturing of the same according to the eleventh embodiment of the present invention; and

FIG. 32 is a view explaining a semiconductor device and a method for manufacturing of the same according to the twelfth embodiment of the present invention.

### DETAIL DESCRIPTION OF THE PREFERED EMBODIMENTS

A description will now be given, with reference to the drawings, of embodiments of the present invention.

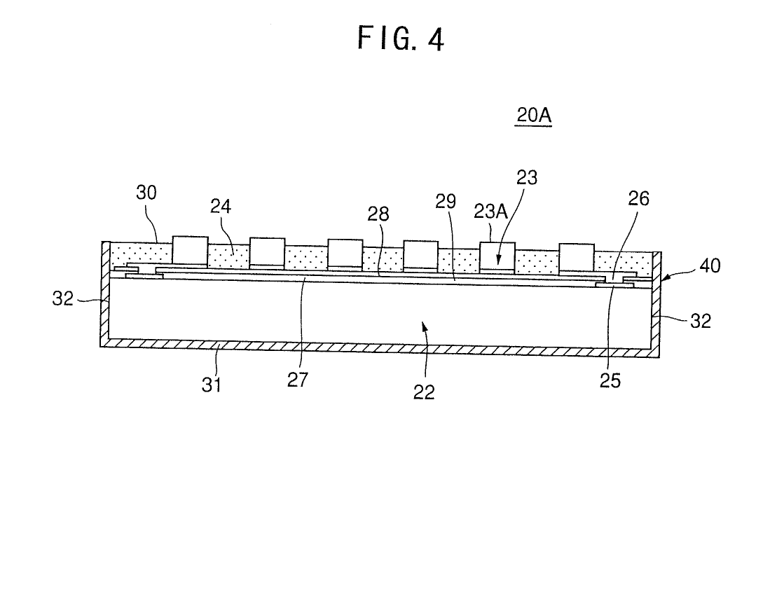

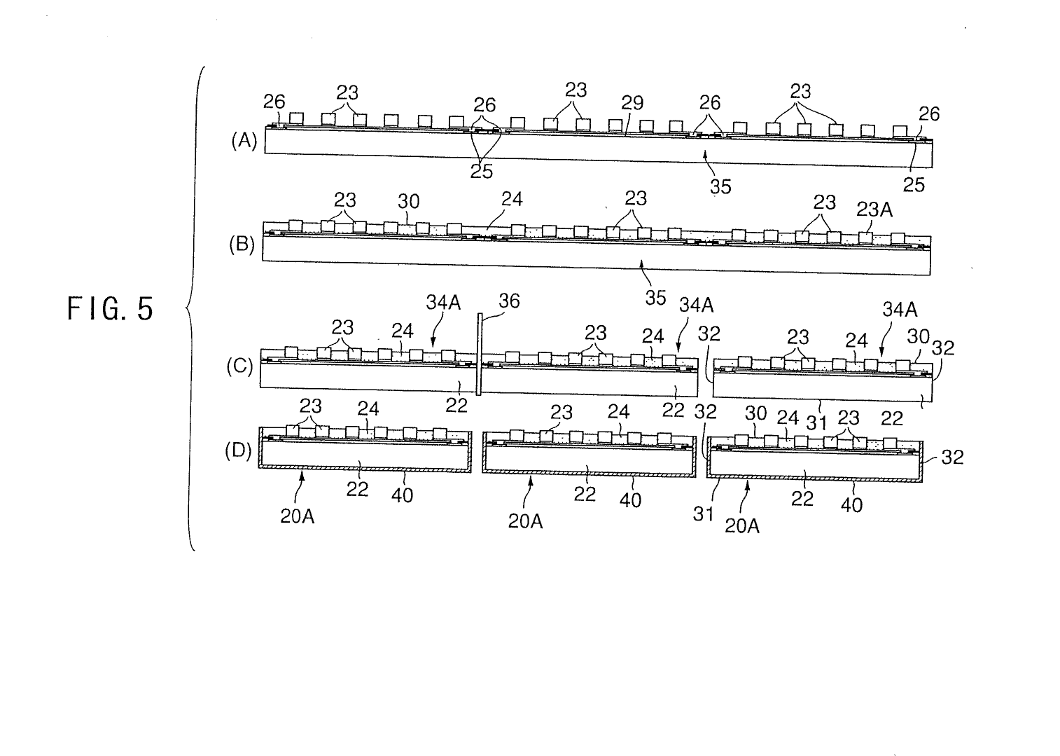

FIG. 4 is a view showing a semiconductor device 20A according to the first embodiment of the present invention. FIG. 5 is a view explaining a method for manufacturing of the semiconductor device 20A.

Referring to FIG. 4, the semiconductor device 20A is of a so-called chip size package (CSP) type. The semiconductor device 20A includes a semiconductor element 22, a seal resin 24, projection electrodes 23, and an organic material layer 40.

The semiconductor element 22 has an electrode 25 and an insulting film 27 such as a silicon nitride film. The electrode 25 and the insulting film 27 are formed on a circuit surface 29. A resin film 28 such as a polyimide is formed on an upper part of the insulting film 27. Also, a rewire 26, functioning as an interposer, is formed on the circuit surface 29.

One end part of the rewire 26 is connected with the electrode 25 through an opening. The opening is formed on an opposite place to the insulting film 27 and the electrode 25 in the resin film 28. The projection electrode 23 is formed on another end part of the rewire 26. In this patent specification, the “interposer” is defined as a constructive element which contributes to an electric connection between the semiconductor element 22 and an external connection terminal such as the projection electrode 23.

The electrode 23 is made from copper for example. The electrode 23 is exposed from the circuit surface 29. A height of the electrode 23 from the circuit surface 29 is approximately 100 μm. As described above, a lower end part of the projection electrode 23 is connected with the rewire 26. Thus, the projection electrode 23 is electrically connected with the semiconductor element 22 by the rewire 26.

The seal resin 24 is a resin of an epoxy group for example. The resin 24 is formed on a side of the circuit surface 29 of the semiconductor element 22. An end part 23A of the projection electrode 23 is projected a little and exposed from a surface of the seal resin 24 (hereinafter “connect surface 30”) in a state where the seal resin 24 is formed.

The organic material layer 40 is made from an organic material such as a polyparaxylylene or polyimide. The organic material layer 40 is formed by the vapor phase growth method. It is preferable that the organic material layer 40 has a thickness of more than 5 μm and less than 20 μm. The thickness of the organic material layer 40 is appropriately set up on the basis of a structure of a handling apparatus which handles the semiconductor device 20A.

In the semiconductor device 20A according to the present embodiment, the organic material layer 40 is formed on a back surface 31 of the semiconductor element 22, which is opposite to the connect surface 30. The organic material layer 40 is also formed on a side surface 32 of the semiconductor element 22 and the seal resin 24. With the above-mentioned structure, the organic material layer 40 plays a role of a support member for the semiconductor element 22 and the seal resin 24. Accordingly, chipping or cracking is prevented from occurring on the semiconductor element 22 when the semiconductor device 20A is handled.

Next, referring to FIG. 5, a method for manufacturing the above mentioned semiconductor device 20A will be explained.

For manufacturing the semiconductor device 20A, an electric circuit, forming a semiconductor element 22, is formed on a semiconductor substrate 35 (wafer). At the same time, the insulting film 27 and the resin film 28 are formed on the circuit surface 29. Next, the projection electrode 23 is formed on the circuit surface 29, in an element forming process. FIG. 5-(A) shows a semiconductor substrate 35 in a state where the element forming process is completed.

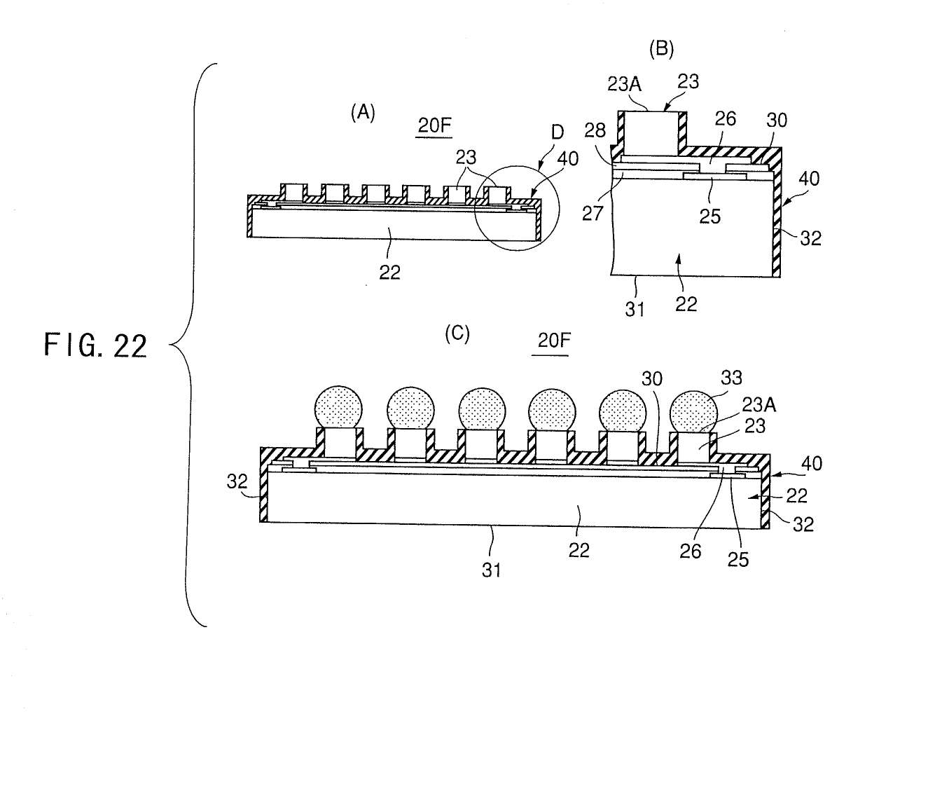

The projection electrode 23 can be formed by the wet plating and the photolithography. The projection electrode 23 can be also formed by the stud-bump (ball-bump) instead of the wet plating and the photolithography. It is preferable that a height of the projection electrode 23 from the circuit surface 29 is less than 100 μm. A solder ball 33 is arranged on the projection electrode 23, as shown in FIG. 22. For the purpose of preventing the projection electrode 23 from being corroded by a solder, a plurality of thin film layers may be formed on the end part 23A of the projection electrode 23.

After the projection solder 23 is formed, the seal resin 24 is formed on the semiconductor substrate 35, in a sealing process. A pressure forming method, a screen print method, or a potting method can be used as a concrete method for forming the seal resin 24. When the seal resin 24 is formed, the end part 23A of the projection electrode 23 is formed as it is exposed a little from the upper surface of the seal resin 24, namely the connect surface 30. As described above, an epoxy resin is used as a material for the projection electrode 23. It is preferable that a silica is included in the projection electrode 23.

As shown in FIG. 5-(C), after the seal resin 24 is formed, a semiconductor substrate 35 is cut into respective semiconductor elements by a dicing blade 36 in a cutting process, so that a semiconductor element body 34A is formed.

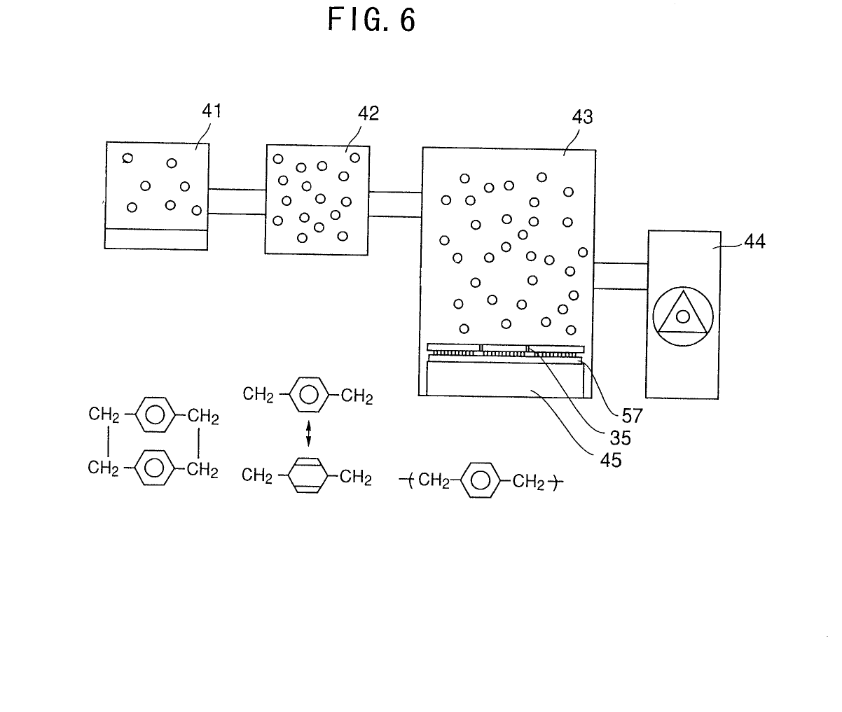

After the cutting process is completed, a film forming process is carried out in order to form the organic material layer 40. In this film forming process, as shown in FIG. 6, a film 57 is arranged on the connect surface 30 of the semiconductor substrate 35. A film of an insulating and organic material is formed on the semiconductor substrate 35 by the chemical vapor deposition in a state where the end part 23A of the projection electrode 23 and an upper surface of the seal resin 24 are covered with the film 57.

Referring to FIG. 6, a concrete method for forming the organic material layer 40 will be explained. Here, an example, in which a polyparaxylylene is used as the insulating and organic material, will be explained.

The organic material layer 40 will be formed by the chemical vapor deposition (CVD). A vapor deposition apparatus for the chemical vapor deposition has a structure in which a vaporization room 41, a heat decomposition room 42, an evacuated vapor deposition room 43, and a vacuum pump 44 are connected as a line, as shown in FIG. 6. The vaporization room 41, the heat decomposition room 42, and the evacuated vapor deposition room 43 are respectively in an evacuated state with a designated pressure such as 0.1 Toor.

The vaporization room 41 is used for vaporizing a diparaxylylene of a dimer which is a material of polyparaxylylene. The diparaxylylene vaporized in the vaporization room 41 moves to the heat decomposition room 42 heated with a heat of approximately 600 centigrade. In the heat decomposition room 42, the diparaxylylene is changed to diradicalparaxylylene which is a radical monomer by heat decomposition. The diradicalparaxylylene is introduced into the evacuated vapor deposition room 43.

On the other hand, the semiconductor substrate 35 (the semiconductor element body 34A) in a state where the above-described cutting process is completed, is mounted on a stage 45 in the evacuated vapor deposition room 43. The diradicalparaxylylene, introduced into the evacuated vapor deposition room 43, is adsorbed to the semiconductor substrate 35 (the semiconductor element body 34A) and occurs a polymerized reaction. Hence, the polyparaxylylene layer is formed on a surface of the semiconductor substrate 35 (the semiconductor element body 34A). This polyparaxylylene layer becomes the organic material layer 40.

The absorptive and polymerized reactions in the evacuated vapor deposition room 43 may be carried out in a state with a normal temperature such as an approximately 25 centigrade. Also, the organic material layer 40 is formed by the above-mentioned chemical vapor deposition. Therefore, it is possible to form the film of the organic material layer 40 on all of places which are not masked by the film 57 of the semiconductor substrate 35 (the semiconductor element body 34A).

On the basis of completing the film forming process, as shown in FIG. 5-(D), the semiconductor device 20A, in which the organic material layer 40 is formed on the back surface 31 and the side surface 32, is manufactured.

According to the above-mentioned method for manufacturing, the organic material layer 40 is formed by forming a film of the organic material in a vapor phase with the chemical vapor deposition. Therefore, it is possible to form the organic material layer 40, by applying a vapor phase growth apparatus used for forming a circuit on the semiconductor substrate 35. Furthermore, it is possible to form the organic material layer 40 with a constant film thickness regardless of a size of the semiconductor substrate 35, by forming a film of the organic material in the vapor phase.

In case of that a resin film instead of the organic material layer 40 is formed, it is necessary to use an expensive mold to form the resin film. Contrary, the mold is not needed for the chemical vapor deposition. Rather, as described above, it is possible to form the organic material layer 40 by applying the vapor phase growth apparatus for forming the circuit. Thus, as compared with the method for forming the resin film, it is possible to manufacture the semiconductor device 20A with a low manufacturing cost. Hence, it can be attempted to reduce a cost of the semiconductor device 20A.

Furthermore, it is possible to form the organic material layer 40 on the back surface 31 and the side surface 32 of the semiconductor device 20B, by carrying out the film forming process after the cutting process is completed. An handling tool is contacted with the back surface 31 and the side surface 32 when the semiconductor device 20A is handled. Hence, the organic material layer 40 plays a role of a support member because the organic material layer 40 is formed on the back surface 31 and the side surface 32. Accordingly, chipping or cracking is reliably prevented from occurring on the semiconductor device 20A (the semiconductor element 22) at the time of handling the semiconductor device 20A.

As described above, the organic material layer 40 plays a role of a support member because the organic material layer 40 is formed on the back surface 31. Accordingly, even if there is a difference between the semiconductor element 22 and the seal resin 24 with respect to thermal expansion coefficients, warping is prevented from occurring as to the semiconductor element 22.

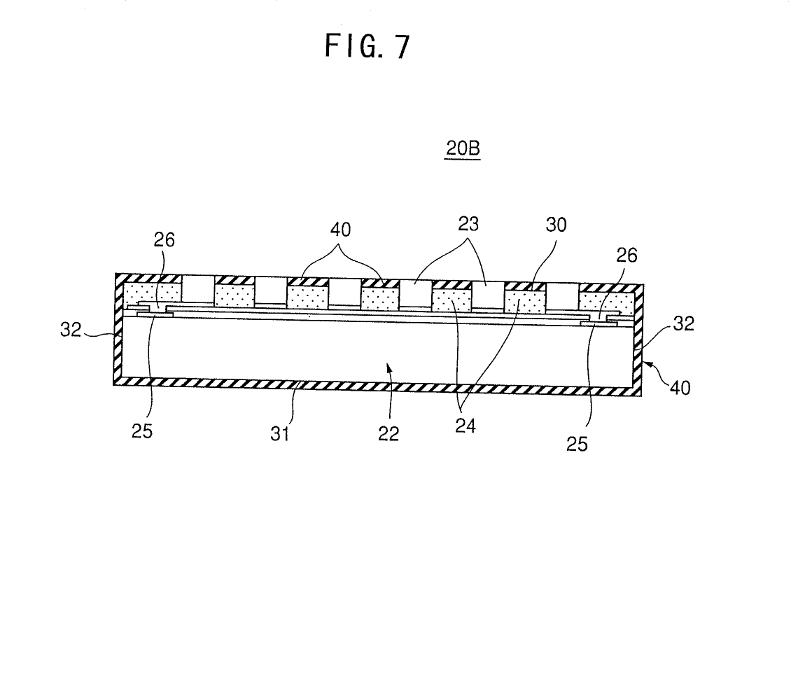

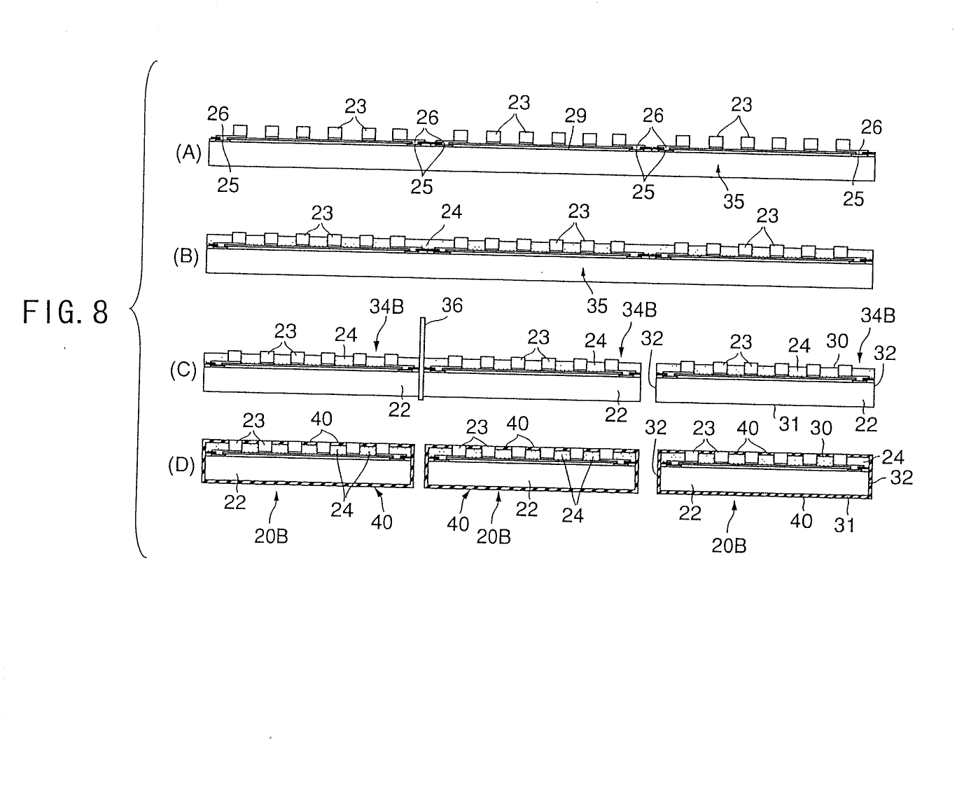

FIG. 7 is a view showing a semiconductor device 20B according to the second embodiment of the present invention. FIG. 8 is a view explaining a method for manufacturing of the semiconductor device 20B.

In FIGS. 7 and 8, parts that are the same as the parts shown in FIGS. 4 to 6 with respect to the first embodiment are given the same reference numerals in, and explanation thereof will be omitted, as well as the following and other embodiments which will be explained.

In the first embodiment, the semiconductor device 20A has a structure in which the organic material layer 40 is arranged on only the back surface 31 and the side surface 32. Contrary, in this embodiment, the semiconductor device 20B has a structure in which the organic material layer 40 is formed on not only the back surface 31 and the side surface 32 but also the connect surface 30.

The organic material layer 40 is formed on the connect surface 30 except a place where the projection electrode 23 is formed. Accordingly, there is no obstacle to an electric connection between the projection electrode 23 and an outside connect apparatus such as a connect board, even if the organic material layer 40 is formed on the connect surface 30.

Thus, in this embodiment, the semiconductor device 20B has a structure in which the organic material layer 40 is formed on both the connect surface 30 and the back surface 31. Therefore, warping is reliably prevented from occurring as to the semiconductor device 20B, as compared with the structure of the semiconductor device 20A in which the organic material layer 40 is formed on only the back surface 31.

Manufacturing processes, shown in FIG. 8-(A) to FIG. 8-(C), are same as the processes shown in FIG. 5-(A) to FIG. 5-(C). In this embodiment, after a cutting process shown in FIG. 8-(C) is completed, the film 37 for masking is not arranged on all of the connect surface 30. A film, not shown in FIG. 8, is arranged in a state where the only end part 23A of the projection electrode 23 is masked. The film forming process is carried out on the above-mentioned film 37. Therefore, as shown in FIG. 8-(D), the organic material layer 40 can be formed on the connect surface 30 except the end part 23A of the projection electrode 23, in addition to the back surface 31 and the side surface 32.

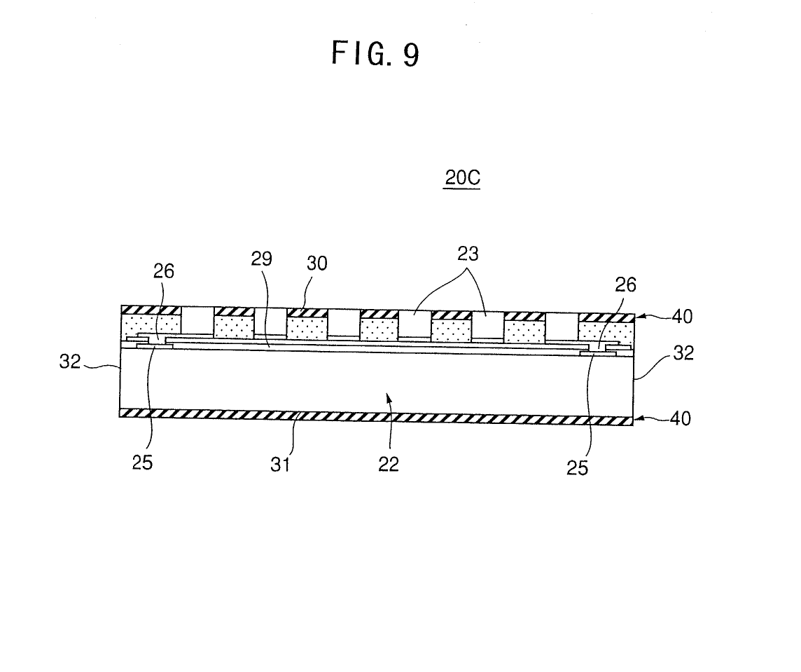

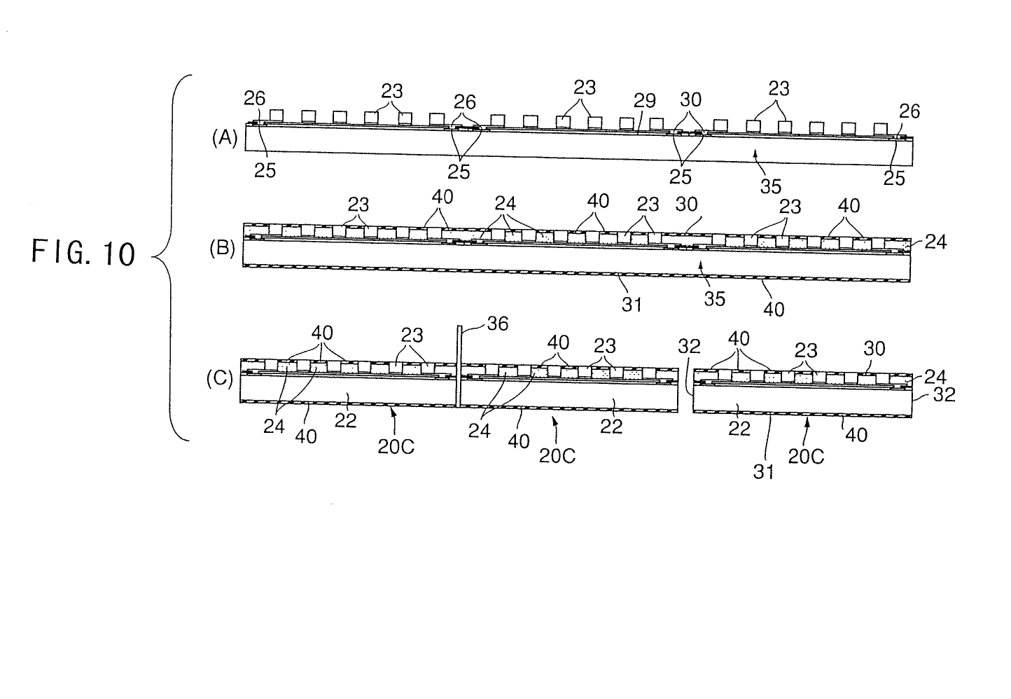

FIG. 9 is a view showing a semiconductor device 20C according to the third embodiment of the present invention. FIG. 10 is a view showing a method for manufacturing of a semiconductor device 20C.

In this embodiment, the organic material 40, playing a role of a support member, is not formed on the side surface 32 of the semiconductor device 20C, as shown in FIG. 9. In case of that the handling tool does not contact with the side surface 32, the organic material 40 may not be formed on the side surface 32. Hence, it is possible to reduce the amount of the organic material for use and the cost of the semiconductor device 20C.

Also, the organic material layer 40 is formed on both the connect surface 30 and the back surface 31. Therefore, warping is prevented from occurring as to the semiconductor device 20C.

FIG. 10 is a view showing a method for manufacturing of a semiconductor device 20C. As shown in FIG. 10-(A), firstly the projection electrode 23 is formed on the semiconductor substrate 35 in the element forming process, and then the seal resin 24 is formed in the sealing process.

According to the respective manufacturing methods of the semiconductor device 20A in the first embodiment and the semiconductor device 20B in the second embodiment, the cutting process is carried out after the sealing process as shown in FIG. 5-(C) is completed. After that, the film forming process is carried out. Contrary, in this embodiment, the film forming process is carried out before the cutting process is carried out.

FIG. 10-(B) shows a state in which the film forming process is completed so that the organic material layer 40 is formed on the semiconductor substrate 35. In this embodiment, the organic material layer 40 is formed on both the connect surface 30 and the back surface 31. After the film forming process is completed, the semiconductor substrate 35 is cut into respective semiconductor elements 22 by using the dicing blade 36 in the cutting process, so that the semiconductor device 20C is completed to be manufactured, as shown in FIG. 10-(C).

In the method for manufacturing in this embodiment, the organic material layer 40 is formed by forming a film of the organic material in the vapor phase. Therefore, it is possible to reduce the expenses for manufacturing. Also, it is possible to form the organic material layer with a constant thickness of the film regardless of the size of the semiconductor substrate 35. In this embodiment, the organic material layer 40 is not formed on the side surface of the semiconductor device 20C, because the cut process is carried out after the film forming process is completed.

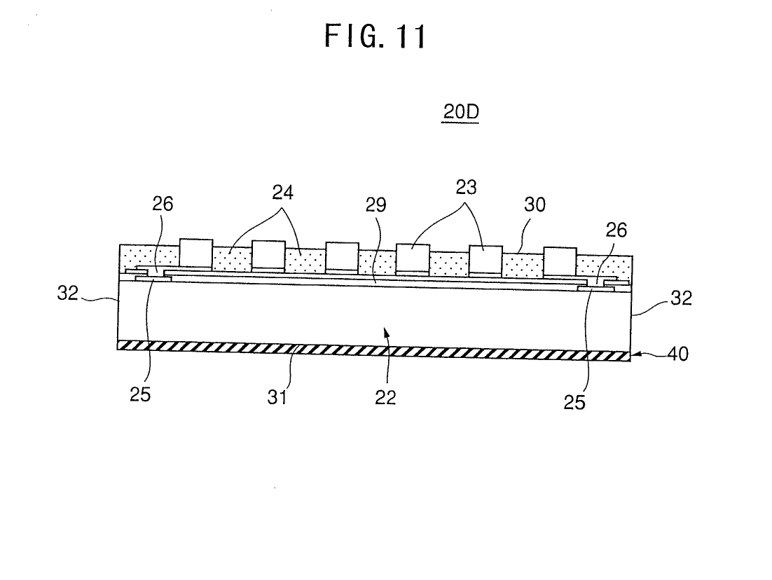

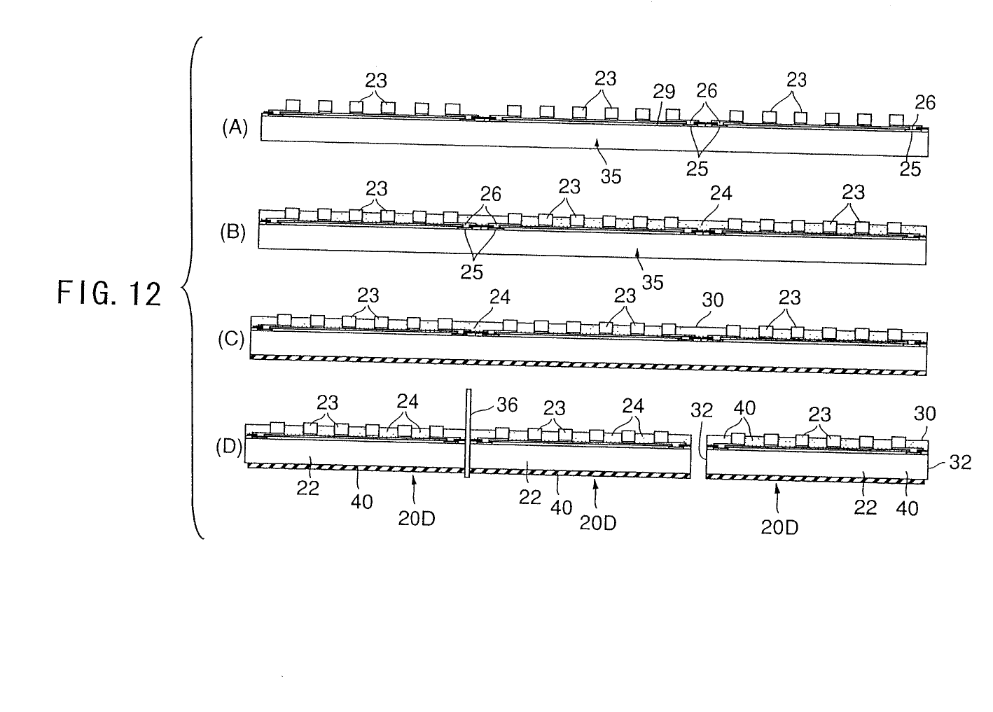

FIG. 11 is a view showing a semiconductor device 20D according to the fourth embodiment of the present invention. FIG. 12 is a view showing a method for manufacturing of the semiconductor device 20D.

The semiconductor device 20D in this embodiment has a structure in which the organic material layer 40 is removed from the connect surface 30 in the semiconductor device 20C. Thus, the semiconductor device may have a structure in which the organic material layer 40 is formed on only the back surface 31.

That is, if there is a big difference between the semiconductor element 22 and the seal resin 24 with respect to thermal expansion coefficients, a big difference of the expansion occurs when the heat is applied, so that big warping occurs. Contrary, in case of that there is a small difference between the semiconductor element 22 and the seal resin 24 with respect to thermal expansion coefficients, the warping is small.

Accordingly, it is possible to select the structure in the second embodiment or the third embodiment on the basis of the degree of occurrence of warping, so that warping can be prevented from occurring. Furthermore, it is possible to reduce the amount of the organic material for use in the semiconductor device 20D having the structure in which the organic material layer 40 is formed on only the back surface 31.

It is possible to manufacture the semiconductor device 20D by an almost equal method to the method for manufacturing the semiconductor device 20C shown in FIG. 10. They are different in that a film not shown in FIG. 12 is arranged on the connect surface 30 in the method for manufacturing the semiconductor device 20D. Therefore, the organic material layer 40 is not formed on the connect surface 30 in the method for manufacturing the semiconductor device 20D.

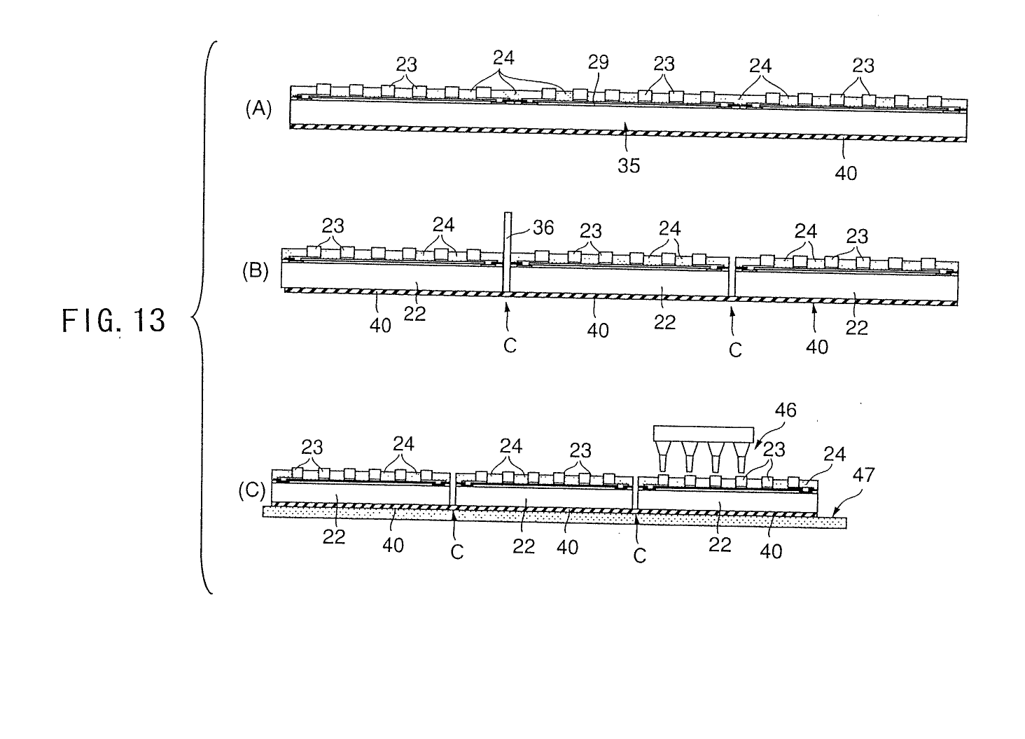

FIG. 13 is a view explaining another method for manufacturing of a semiconductor device 20D. This method includes a test process in which the semiconductor element 22 is tested.

The semiconductor device 20D has a miniaturized CSP structure. Accordingly, if a test is conducted to the respective semiconductor devices 20D after they are cut into pieces, the test to the pieces becomes complicated. As to each of the small sized semiconductor device 20D, it is necessary to carry and position a position for the test. After that, the test is conducted by connecting with a probe pin. Accordingly, in this case, it is very complicated to position the position for the test, so that the efficiency of the test is reduced.

If the test is conducted for the semiconductor wafer before the cut process for cutting the semiconductor device into pieces is carried out, there is a disadvantage. That is, if there is a difference between the semiconductor substrate 35 and the seal resin 24 with respect to thermal expansion coefficients, the semiconductor substrate 35 is bent, so that the reliance of the test is reduced.

As shown in FIG. 13-(B), in the process of the element cut process, when the semiconductor substrate 35 is cut, the dicing blade 36 is used for dicing only the semiconductor substrate 35, so that the organic material layer 40 is not cut. That is, after the element forming process, sealing process, and the film forming process as shown in FIG. 13-(A) are completed, the semiconductor device 35 is cut into the respective semiconductor elements 22 in a state where the organic material layer 40 is remained. Thus, although he semiconductor device 35 is cut into the respective semiconductor elements 22 neighboring semiconductor elements 22 are connected each other by the organic material layer 40 at a place where a narrow C shows in FIG. 13-(B).

Next, a plurality of the semiconductor elements 22 connected by the organic material layer 40 are mounted on the stage 47 of the test apparatus in a lump. The test is conducted with the probe pin 46 on the basis of a designated test program, by using a moving mechanism. The probe pin 46 is connected with the projection electrode 23.

In the test process, the test is conducted for the semiconductor element 22 which is cut. Therefore, it is possible to reduce an effect of warping in case of the test is conducted for the semiconductor substrate 35 which is not cut. Hence, it is possible to conduct the test reliably.

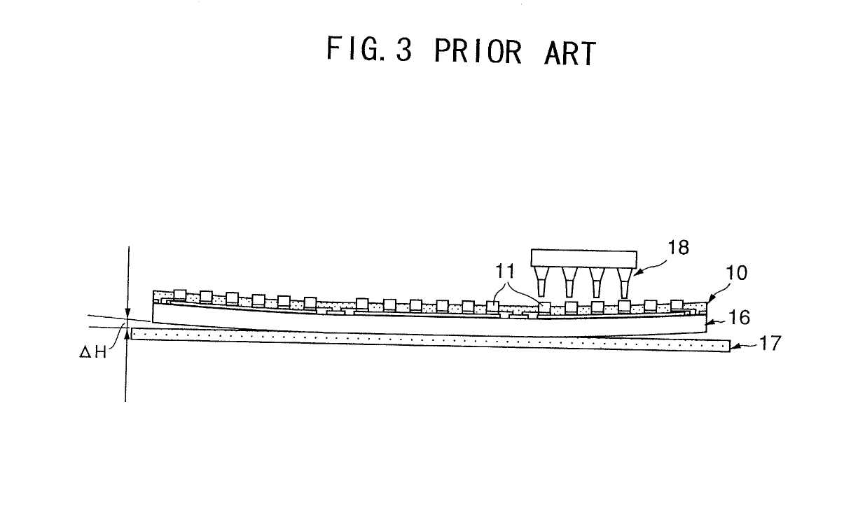

Warping which occurs in respective semiconductor elements 22 is small. On the other hand, as shown in FIG. 3, the big warping, as a whole, occurs in the semiconductor substrate 35 which comprises the consecutive semiconductor elements 22. If the semiconductor substrate 35 is cut into the respective semiconductor elements 22, warping becomes smaller and can be disregarded as to the connection with the probe pin 46. Therefore, if the test is conducted after the semiconductor substrate 35 is cut into the respective semiconductor element 22, it is possible to connect the probe pin 46 with the projection electrode 23 reliably. Thus, it is possible to conduct the test with high reliance.

The semiconductor elements 22 are connected with the organic material layer 40, while they are respectively cut. Therefore, the respective semiconductor elements 22 keep a state where they are positioned by the organic material layer 40. Thus, it is possible to position easily and reliably as to the probe pin 46 and the respective semiconductor elements 22 (the projection electrodes 23). Accordingly, it is possible to conduct the test with high reliance. After the above-mentioned test process is completed, a place in the organic material layer 40, where a narrow C in FIG. 13-(C) shows, is cut in an organic material layer cutting process, so that the respective semiconductor device 20D is completed to be manufactured.

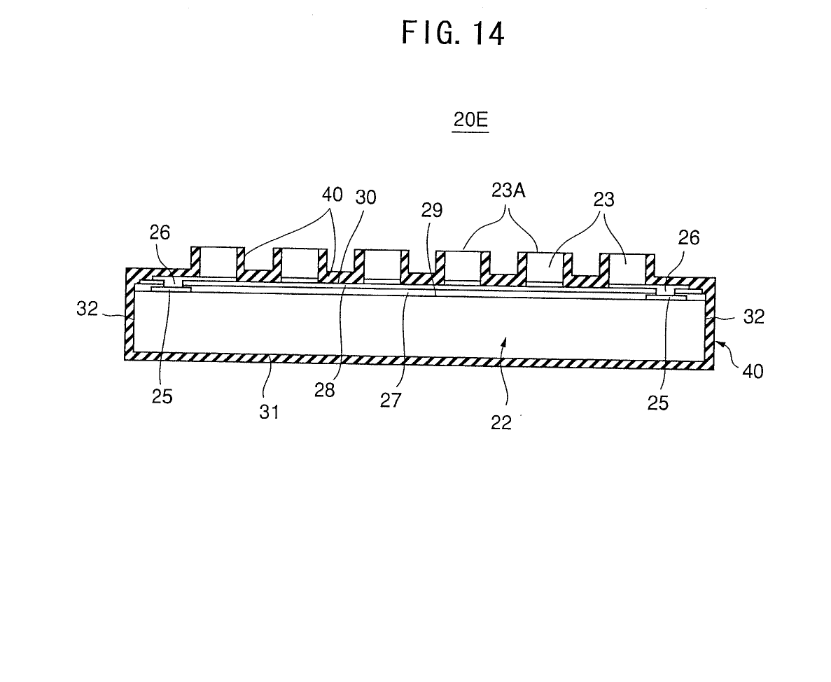

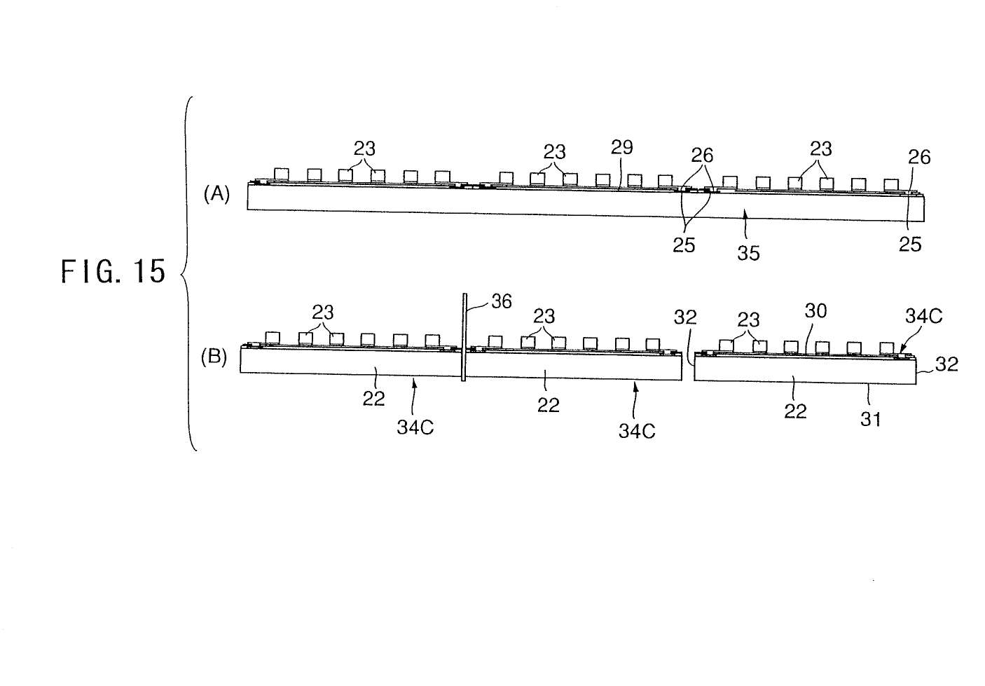

FIG. 14 is a view showing a semiconductor device 20E according to the fifth embodiment of the present invention. FIG. 15 is a view showing a method for manufacturing of a semiconductor device 20E.

The semiconductor devices 20A to 20D as to the first to fifth embodiments respectively have structures in which the seal resin 24 is formed on the circuit surface 29 of the semiconductor element 22. Contrary, the semiconductor device 20E in this embodiment does not include the seal resin 24 as well as the semiconductor device 20F to 20J does not.

The semiconductor device 20E has a structure in which the organic material layer 40 is formed on all of surfaces of the connect surface 30, the back surface 31, and the side surface 32. The organic material layer 40 is not formed on the end part 23A of the projection electrode 23.

With the above-mentioned structure, it is not necessary to use the seal resin 24 because the organic material layer 40 plays a role of the seal resin 24. Hence, it is possible to reduce the cost of the semiconductor device 20E. Also, it is possible to prevent warping from occurring on the semiconductor element 22 because the organic material layer 40 is formed on the connect surface 30 and the back surface 31.

In this embodiment, the semiconductor device 20D does not have the seal resin 24. Therefore, warping due to differences between the seal resin 24 and the semiconductor substrate 35 with respect to thermal expansion coefficients, does not occur. Warping occurs on the semiconductor device 20E because of respective differences of thermal expansion coefficients with respect to the semiconductor element 22 and the insulating film 27, the semiconductor element 22 and the resin film 28, and the semiconductor element 22 and the rewire 26.

The effect of warping due to the above-mentioned difference of thermal expansion coefficients is smaller than that due to the difference of thermal expansion coefficients with respect to the seal resin 24 and the semiconductor element 22. Therefore, the thickness of the organic material layer 40 in this embodiment can be almost equal to that in the semiconductor devices 20A to 20D in the first to fourth embodiments. The organic material layer 40 formed on the back surface 31 and the side surface 32 play a role of that chipping or cracking can be prevented from occurring at the time of handling.

FIG. 15 is a view explaining a method for manufacturing of a semiconductor device 20E. After the element forming process shown in FIG. 15-(A) is completed, the cutting process shown in FIG. 15-(B) is carried out without carrying out the sealing process, so that the semiconductor element body 34C is formed. After the end part 23A of the projection electrode 23 is masked by the film, the film forming process is carried out to the semiconductor element body 34C, so that the above-mentioned semiconductor device 20E is completed to be manufactured.

According to the method for manufacturing the semiconductor device 20E, it is possible to simplify the manufacturing processes for the semiconductor device, because the sealing process for forming the seal resin is not needed. Also, the cost for the semiconductor device 20E can be attempted to be reduced, because the mold for forming the seal resin is not needed. Furthermore, the film forming process is carried out after the cutting process is completed. Accordingly, it is possible to form the organic material layer 40 on the side surface 32 of the semiconductor device 20E. Also, the method for manufacturing the semiconductor device 20E has advantages in that the cost for manufacturing can be reduced and the organic material layer 40 with the constant thickness regardless of the size of the semiconductor device 35 (semiconductor element 22) can be formed, as well as the above-mentioned and respective semiconductor devices in the respective embodiment do.

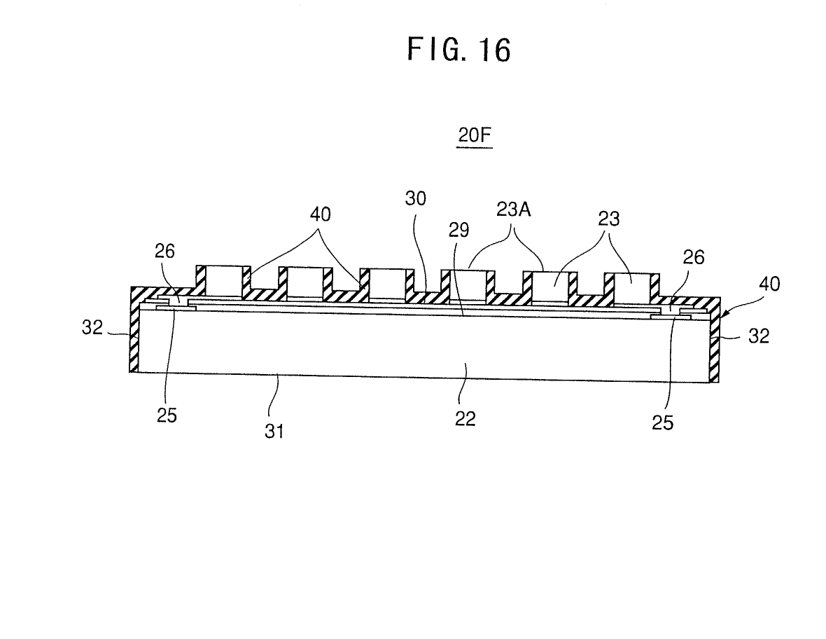

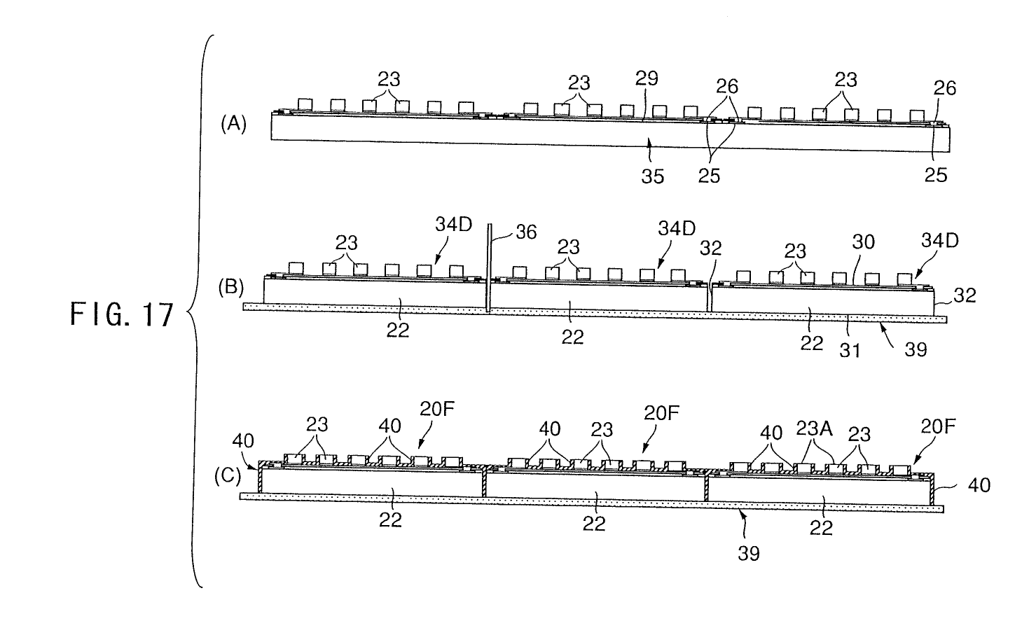

FIG. 16 is a view showing a semiconductor device 20F according to the sixth embodiment of the present invention. FIG. 17 is a view explaining a method for manufacturing of a semiconductor device 20F.

The semiconductor device 20F has a structure in which the organic material layer 40 is removed from the back surface 31 in the semiconductor device 20E. That is, the back surface 31 of the semiconductor element 22 is exposed.

As described above, in case of that the handling tool is contacted with only the side surface 32, the organic material layer 40 may not be formed on the back surface 31 as this embodiment shows. Thus, it is possible to keep small amount of the organic material for forming a film which can be used for the organic material layer 40.

FIG. 17 is a view explaining a method for manufacturing of a semiconductor device 20F. As shown in FIG. 17-(A), after the element forming process is carried out on the semiconductor substrate 35, the film 39 is stuck on the back surface 31 of the semiconductor substrate 35, and then the cutting process by applying the dicing blade 36 is carried out. In this embodiment, only the semiconductor substrate 35 is cut by the dicing blade 36. The film 39 is not cut.

The semiconductor element 22 stuck on the film 39 is provided in the evacuated vapor deposition room 43 as shown in FIG. 6. In the evacuated vapor deposition room 43, the film forming process for forming the organic material layer 40 on the semiconductor element 22 is carried out. The film for masking is arranged on the end part 23A of the projection electrode 23 in advance. Thus, the organic material layer 40 is formed on not only the connect surface 30 other than the end part 23A of the projection electrode 23 but also the side surface 32 which is cut by the dicing blade 36. However, the organic material layer 40 is not formed on the back surface 31 of the semiconductor element 22, because the film 39 is stuck on the back side 31. The semiconductor device 20F is completed to be manufactured by removing the film 39.

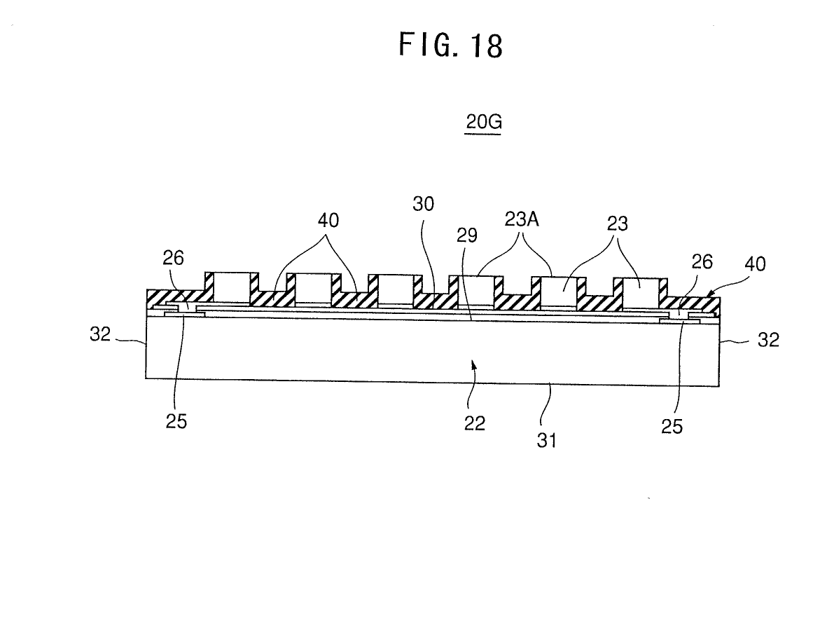

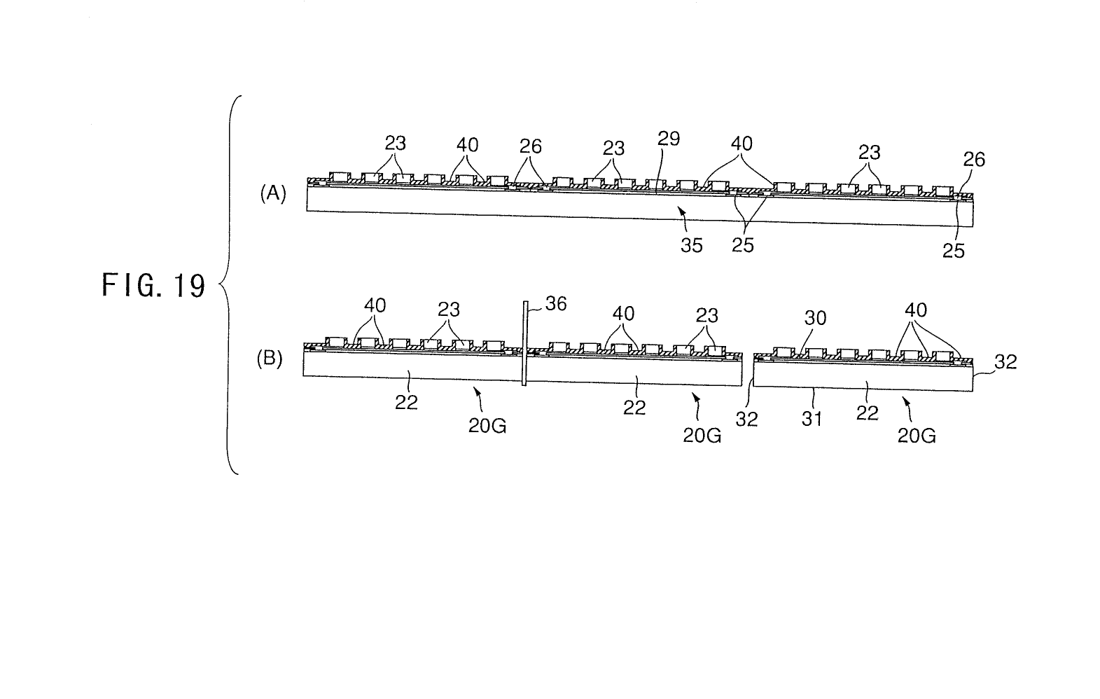

FIG. 18 is a view showing a semiconductor device 20G according to the seventh embodiment of the present invention. FIG. 19 is a view showing a method for manufacturing of a semiconductor device 20G.

The semiconductor device 20G has a structure in which the organic material layer 40 is removed from the back surface 31 and the side surface 32 in the semiconductor device 20E, according to the fifth embodiment. That is, the back surface 31 and the side surface 32 on the semiconductor element 22 are exposed.

In case of that the semiconductor device 20G is not carried by the handling tool, the semiconductor device may have a structure in which the organic material layer 40 is not formed on the back surface 31 and the side surface 32. Thus, an arranging amount of the organic material used for the organic material layer 40, can be reduced.

FIG. 19 is a view showing a method for manufacturing of a semiconductor device 20G. After the element forming process shown in FIG. 19-(A) is completed, the film forming process for forming the organic material layer 40 on the connect surface 30 is carried out. After that, as shown in FIG. 19-(B), the cutting process in which the respective semiconductor elements 22 are cut by using the dicing blade 36, so that the semiconductor device 20G is completed to be manufactured.

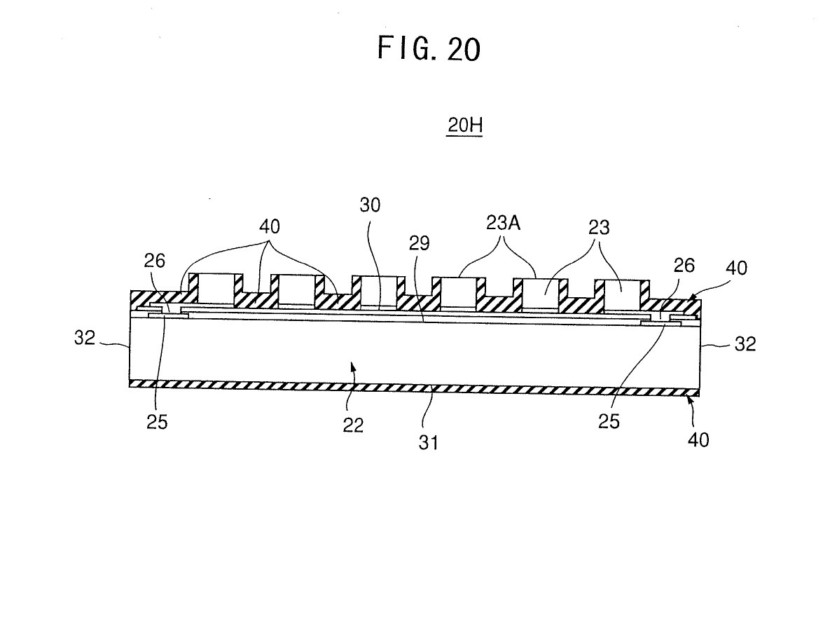

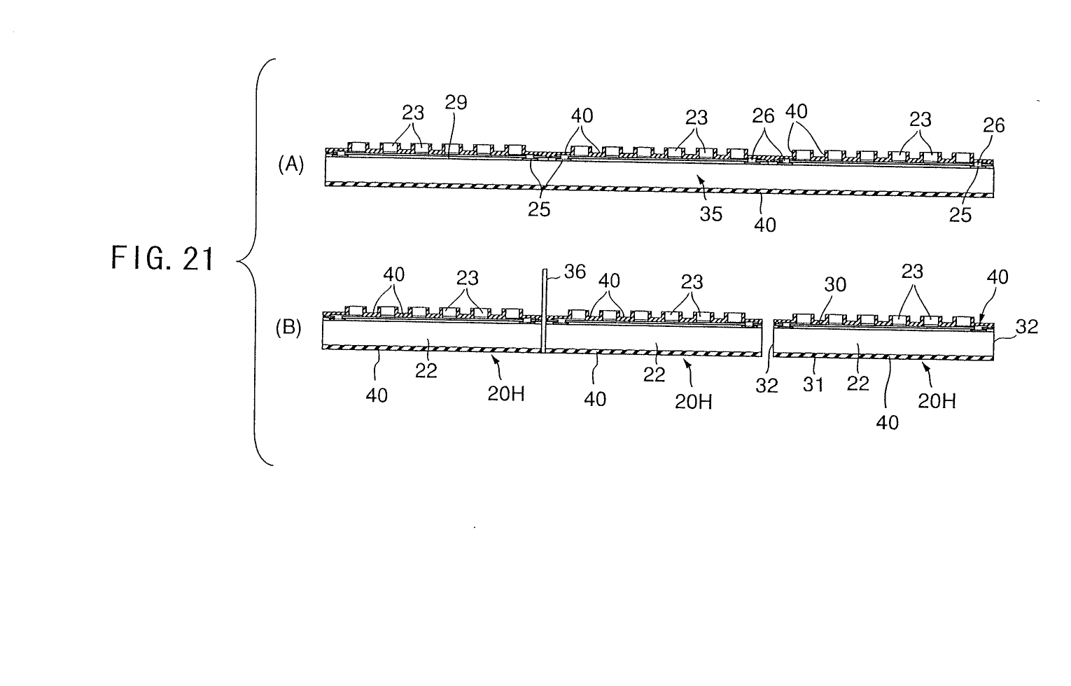

FIG. 20 is a view showing a semiconductor device 20H according to the eighth embodiment of the present invention. FIG. 21 is a view explaining a method for manufacturing of a semiconductor device 20H.

The semiconductor device 20H has a structure in which the organic material layer 40 formed on the side surface 32 is removed. That is, the side surface 32 on the semiconductor element 22 is exposed.

The organic material layer 40 is formed on the connect surface 30 and the back surface 31 in the semiconductor device 20H in this embodiment. Therefore, the semiconductor device 20H is well balanced regarding the top and bottom, in case the semiconductor element 22 is a center. Hence, even if there is a difference between the organic material layer 40 and the semiconductor element 22 with respect to thermal expansion coefficients, the thermal expansion between the organic material layer 40 on the connect surface 30 and the back surface 31 is canceled. Therefore, warping of the semiconductor device 20H is prevented from occurring. This effect can be achieved to the semiconductor device 20E according to the fifth embodiment.

FIG. 21 is a view explaining a method for manufacturing of a semiconductor device 20H.

After the element forming process shown in FIG. 21-(A) is completed, the film forming process 30 for forming the organic material layer 40 on the connect surface 30 and the back surface 31 is carried out. After that, as shown in FIG. 21-(B), the cutting process for cutting the semiconductor substrate 35 into the respective semiconductor elements 22 by using the dicing blade 36, so that the semiconductor device 20H is completed to be manufactured.

The manufacturing processes shown in FIGS. 15, 17, 19, and 21 can be simplified as well as in this embodiment, because the process for forming the seal resin 24 is not needed. Also, the cost for the respective semiconductor devices 20E-20H can be reduced because the mold is not needed. Furthermore, the vapor phase growth apparatus for forming the circuit on the semiconductor substrate 35 can be used, because the organic material layer 40 is formed by forming the film of the organic material in the vapor phase. Therefore, the cost of manufacturing can be reduced. Also, the organic material layer 40 with a constant thickness regardless of the size of the semiconductor substrate 35 can be formed, because the organic material layer 40 is formed by film forming of the organic material in the vapor phase.

Meanwhile, the above-mentioned semiconductor devices 20A to 20H respectively have a structure in which the projection electrode 23 can be used as a direct external connection terminal. The solder ball 33 arranged on the projection electrode 23 may be used as the external connection terminal. FIG. 22 shows the semiconductor device 20F having a structure in which the solder ball 33 arranged on the projection electrode 23 is used as the external connection terminal. FIG. 22-(A) shows the above-mentioned semiconductor device 20F. FIG. 22-(B) shows an enlarged part shown with an arrow D in FIG. 22-(A). FIG. 22-(C) shows the semiconductor device 20F in which the solder ball 33 is arranged on the projection electrode 23.

However, as shown in FIG. 22-(B), the semiconductor device 20F has a structure in which only the end part 23A is exposed from the organic material layer 40 as to the projection electrode 23. Hence, in case of that the solder ball 33 is arranged, the solder ball 33 is connected with only the end part 23A of the projection 23. Thus, an area for connecting the solder ball 33 with the projection electrode 23 is so small that the installation of the solder ball 33 may not be enough strong.

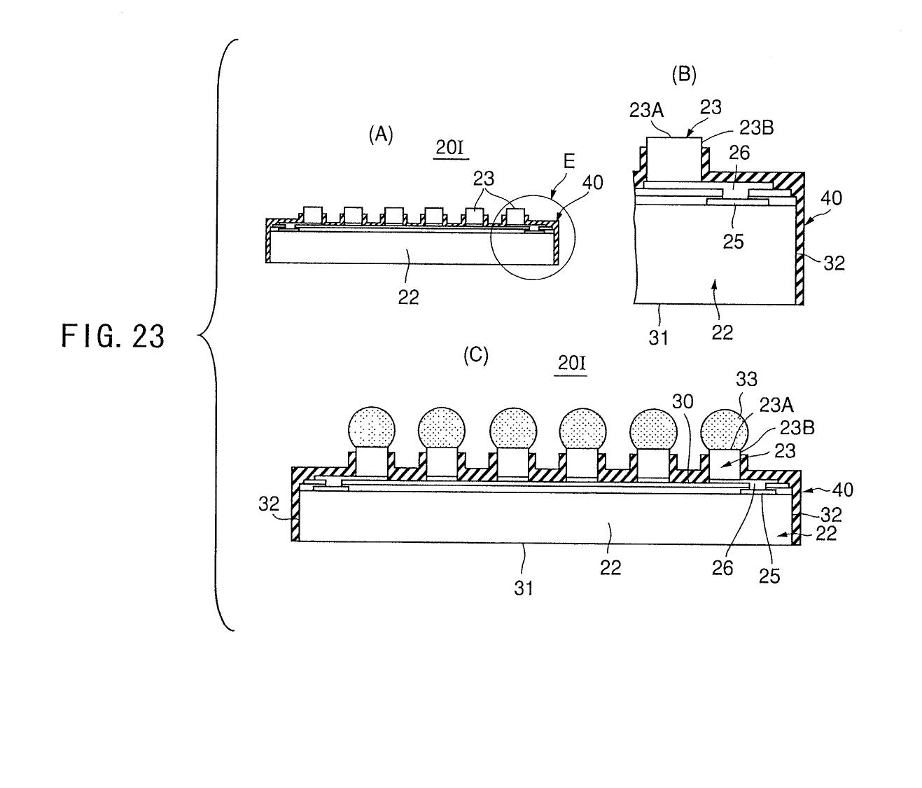

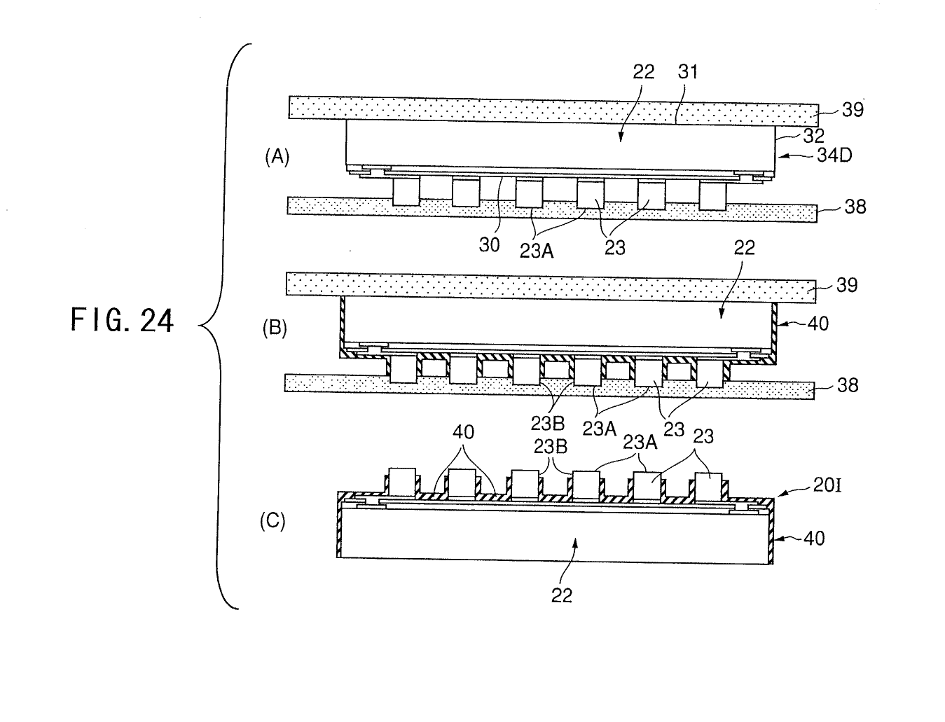

FIG. 23 is a view showing a semiconductor device 20I according to the ninth embodiment of the present invention. FIG. 24 is a view explaining a method for manufacturing of a semiconductor device 20I.

The semiconductor device 20I in this embodiment has a structure in which an end side surface part (hereinafter an “exposed part 23B”) is also exposed from the organic material layer 40, in order to solve the above-mentioned disadvantages as to the semiconductor device shown in FIG. 22. That is, in this embodiment, the exposed part 23B, in addition to the end part 23A of the projection 23, is also exposed from the organic material layer 40.

With the above-mentioned structure, in case of that the solder ball 33 is arranged on the projection electrode 23, the solder ball 33 is connected with not only the end part 23A of the projection 23 but also the exposed part 23B. Hence, according to this embodiment, it is possible to expand a connection area between the projection electrode 23 and the solder ball 33. Therefore, the solder ball 33 reliably is prevented from leaving from the projection electrode 23.

FIG. 24 is a view explaining a method for manufacturing of a semiconductor device according to the ninth embodiment of the present invention. As shown in FIG. 24-(A), the film 39 is stuck on the back surface 31 of the semiconductor element body 34D (the semiconductor substrate 35). The projection electrode 23 is pressed to the flexible film 38 having an elasticity. For example, PTFE (polytetrafluoroethylene), PET (polyethyleneterephthalate), or polyimide can be used as the flexible film 38

Accordingly, the end part of the projection electrode 23 is buried into the flexible film 38 by pressing the electrode 23 on the flexible film 38. The film forming process is carried out in a state shown in FIG. 24-(A).

FIG. 24-(B) shows a state in which the film forming process is completed. As shown in FIG. 24-(B), the film forming process as to the organic material layer 40 is carried out in a state where the end part of the projection electrode 23 is buried in the flexible film 38. Therefore, the organic material layer 40 is formed on neither the end part 23A of the projection electrode 23 nor an adjacent side surface which corresponds to the exposed part 23B.

Next, the flexible film 38 and the film 39 are removed. The semiconductor device 20I having a structure in which the end part 23A of the projection electrode 23 and the exposed part 23B are projected from the organic material layer 40 can be manufactured.

According to the above described method for manufacturing, it is possible to make the end part 23A of the projection electrode 23 and the exposed part 23B exposed from the organic material layer 40, by just pressing the projection electrode 23 on the flexible film 38.

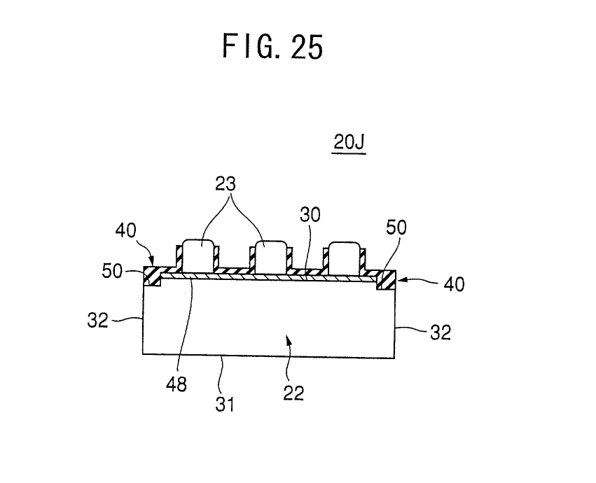

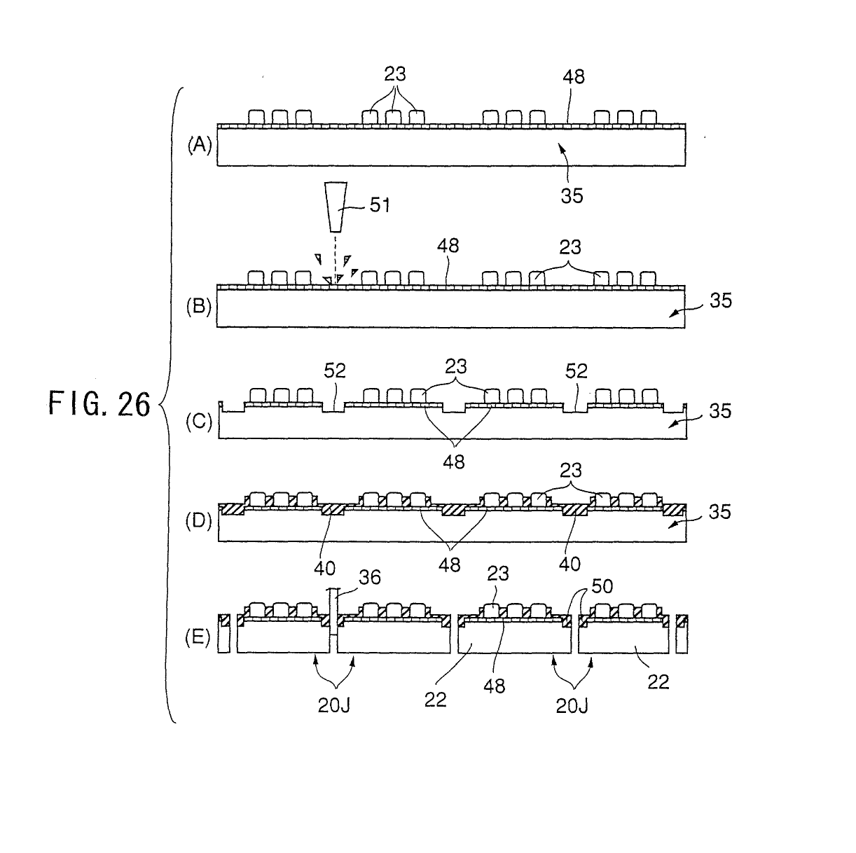

FIG. 25 is a view showing a semiconductor device 20J according to the tenth embodiment of the present invention. FIG. 26 is a view showing a main point of a method for manufacturing of a semiconductor device 20J.

The semiconductor device 20J includes the semiconductor element 22, the projection electrode 23, the organic material layer 40 and the chamfer part 50. On the circuit surface of the semiconductor chip 32A, a thin film made of a contaminant 48 is formed. The contaminant 48 is, for example, a remaining material during the manufacturing process of the semiconductor element 22 or respective processes which are carried out when the electric circuit is formed on the semiconductor substrate 35 such as an impurities diffusion process, a thin film forming process, or photolithography. Or, the contaminant 48 is, for example, a remaining material of the resin film protecting the circuit surface, generally a polyimide film, and remained on the semiconductor substrate 35. The contaminant 48 is an obstacle to make the organic material layer 40 grow.

As to the contaminant 48 formed on the semiconductor element 22, an outer circumference part of the contaminant 48 is removed. The chamfer part 50 is, as described later, formed by removing the contaminant 48 with a laser process. Also, a formed area in the chamfer part 50 is positioned to obtain as much areas as possible on the outer circumference part of the circuit surface of the semiconductor element 22.

The semiconductor device 20J in this embodiment is in a state where a part of the circuit surface of the semiconductor chip 30A is exposed from the contaminant 48, by forming the chamfer part 50. The chamfer part 50 has a step to the circuit surface of the semiconductor element 22, so that a connection area between the organic material layer 40 and the semiconductor element 22 is wide.

The contaminant 48, causing an inferior connection, does not exist on the chamfer part 50. Also, the connection area between the semiconductor element 22 and the organic material layer 40 is wide. Accordingly, the semiconductor element 22 and the organic material layer 40 connect each other with strong connection force. Therefore, even if the contaminant 48 is on the semiconductor element 22, the organic material layer 40 is prevented from coming off from the semiconductor element 22, because the connection force between the semiconductor element 22 and the organic material layer 40 on the chamfer part 50 is strong. Thus, it is possible to improve the reliance of the semiconductor device 20J.

Next, a method for manufacturing of the semiconductor device 20J will be explained.

FIG. 26 is a view explaining a main point of a method for manufacturing of a semiconductor device 20J. In FIG. 26, particularly, a method for forming the chamfer part 50 is described.

FIG. 26-(A) shows the semiconductor substrate 35 in a state where the element forming process is completed. In this state, the contaminant 48 is stuck on the whole surface of the upper surface of the semiconductor device 35. The contaminant 48 is a remaining material made of particles which occur when respective processes to form the electric circuit are carried out or the resin film protecting the circuit surface is formed. The contaminant 48 is stuck on the semiconductor substrate 35.

The contaminant 48 is removed from the above-mentioned semiconductor substrate 35, and a forming groove for chamfer process, in which a groove for chamfer 52 is formed, is carried out. In the forming groove for chamfer process, as shown in FIG. 26-(B), the laser 51 is shone on the semiconductor substrate 35 having a surface on which a film of the contaminant 48 is formed. Hence, firstly the contaminant 48 is removed. The groove for chamfer 52 as shown in FIG. 26-(C) is formed by the laser 51 even after the contaminant 48 is removed.

A laser occurring apparatus, which highly outputs a short pulse laser such as an exima laser, a YAG laser, or a CO₂ laser, may be used. Concretely, the laser occurring apparatus having 250 nm-1100 nm of the oscillation wavelength is preferable.

The position which is exposed to the laser, namely the position on which the groove 52 for chamfer is formed, includes a dicing place where the semiconductor element 22 is cut into pieces. The width of the groove is set in a state it is wider than the width of the dicing blade 36.

After the forming groove for chamfer process is completed, the film forming process in which the organic material layer 40 is formed on the semiconductor substrate 35 on which the groove 52 for chamfer is formed, is carried out. FIG. 26-(D) shows a state where the organic material layer 40 is formed on the semiconductor substrate 35. As shown in FIG. 26-(D), the organic material layer 40 is formed on the connect surface 30 of the semiconductor substrate 35. Therefore, the organic material layer 40 is formed for burying the groove 52 for chamfer. Since the groove 52 for chamfer is a part where the contaminant 48 is removed, the organic material layer 40 is directly connected with the semiconductor substrate 35.

After the film forming process is completed, the cut process is carried out. In the cut process, as shown in FIG. 26(E), the semiconductor substrate 35 and the organic material layer 40 are cut in a lump at a designated dicing position of the groove 52 for chamfer, by the dicing blade 36. Hence, the semiconductor substrate 35 is cut into the respective semiconductor devices. The groove 52 for chamfer becomes the chamfer part 50 by cutting, so that the semiconductor device 20J is completed to be manufactured.

In this embodiment, the laser 51 is used for removing the contaminant 48 and forming the groove 52 for chamfer. There is a mechanically removing method by using a lapping material or a bite as a method for removing the contaminant. However, in case of that the contaminant 48 is removed by the mechanical process, a residual stress may occur on the semiconductor substrate 35, so that chipping or cracking may occur.

Contrary, in case of that the contaminant 48 is removed by using laser beam 51, the residual stress occurring on the semiconductor substrate 35 can be reduced, as compared with by the mechanical process. Particularly, the laser occurring apparatus 41 having the short pulse width, 250 nm-1100 nm of the oscillation wavelength, is used in this embodiment. Therefore, it is possible to remove the contaminant 48 and form the groove 52 for chamfer, for a moment.

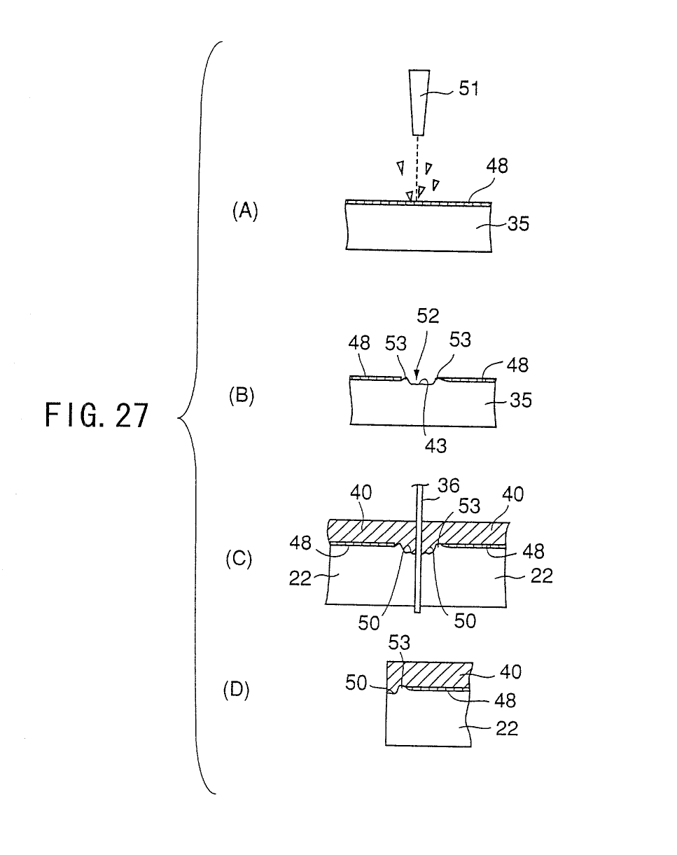

Referring to FIG. 27, a concrete structure of the chamfer part 50 will be explained.

As shown in FIG. 27-(A), the laser 51 is shone on the semiconductor substrate 35 on which the contaminant 48 is stuck, so that the contaminant 48 is removed and the groove 52 for chamfer is formed. FIG. 27-(B) is an enlarged view showing a state in which the groove for chamfer forming process is completed.

As shown in FIG. 27-(B), the contaminant 48 is removed from the groove 52 for chamfer by the laser beam. The groove 52 for chamfer has a dimple form formed by the laser beam. The base part 43 having the dimple form has a rough and minute unevenness surface. An outer circumference part of the base part 43 has a mount part 53, because the semiconductor device 35 is bulged there. Thus, the material of the semiconductor substrate 35 is melted by the laser beam. The material is pushed to the outer circumference part of the base part 43 by energy of the laser beam. This is because the mount part 53 is formed on the outer circumference part of the base part 43.

FIG. 27-(C) shows a state in which the organic material layer 40 is formed on the groove 52 for chamfer having the above structure and the cutting process is carried out by using the dicing blade 36. FIG. 27-(D) shows an enlarged view of an adjacent place of the chamfer part 50 in a state where the cutting process is completed.

As shown in FIG. 27-(A) to FIG. 27-(D), the organic material layer 40 is formed in the groove 52 for chamfer (the chamfer part 50) by forming it on the semiconductor substrate 35. Since the base part 43 of the groove 52 for chamfer (the chamfer part 50) is a rough surface as described above, the organic material layer 40 is in a state where it is in a minute unevenness forming the rough surface. Also, the contaminant 48 is removed from the groove 52 for chamfer (the chamfer part 50), the connection with the organic material layer 40 is strong. Thus, it is possible to connect between the groove 52 for chamfer (the chamfer part 50) and the organic material layer 40. Accordingly, the semiconductor element 22 is reliably prevented from leaving from the organic material layer 40.

Furthermore, as described above, the mount part 53 is formed on the outer circumference part of the groove 52 for chamfer (the chamfer part 50). This mount part 53 is stuck into the organic material layer 40 after the organic material layer 40 is formed. Therefore, the mount part 53 has an anchor effect. The mount part 53 is formed with the semiconductor element 22 in a body. The contaminant 48 is not stuck on the mount part 53. Hence, the connection between the mount part 53 and the organic material layer 40 is strong, so that the semiconductor element 22 is reliably prevented from leaving from the organic material layer 40.

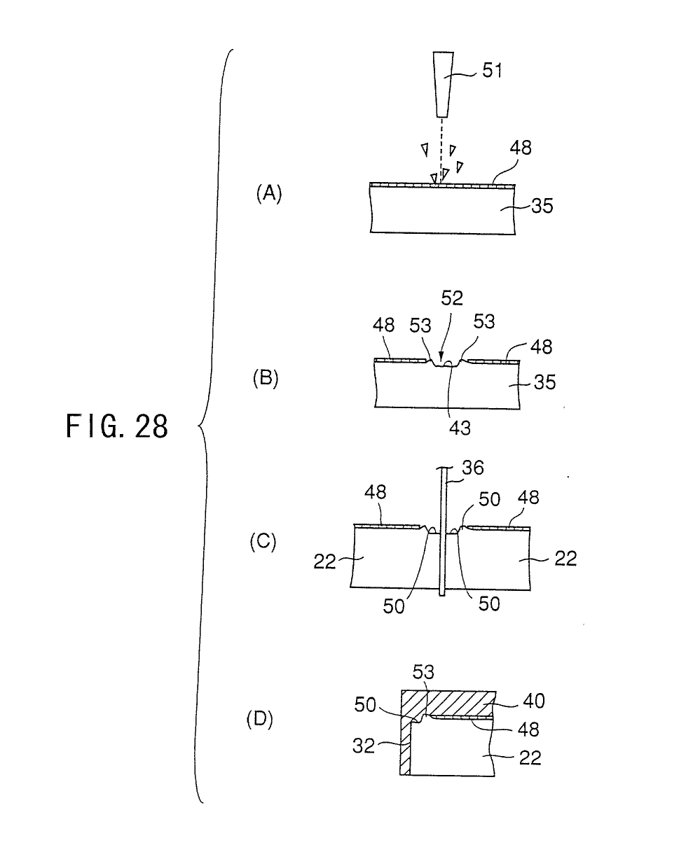

In the embodiments shown in FIGS. 26 and 27, after the groove 52 for chamfer is formed by the laser 51, the organic material layer 40 is formed by carrying out the film forming process. After that, the cutting process is carried out. The film forming process may be carried out after the cutting process is carried out. FIG. 28 shows a method for manufacturing in that the film forming process is carried out after the cutting process is carried out.

FIGS. 28-(A) and 28-(B) are respectively same processes as FIGS. 27-(A) and 28-(B). In the process shown in FIG. 28, the laser 51 is shone on the semiconductor substrate 35 where the contaminant 48 is formed, in order to remove the contaminant 48 and form the groove 52 for chamfer. After that, as shown in FIG. 28-(C), the cutting process, in which the semiconductor substrate 35 is cut into the respective semiconductor elements 22 by dicing blade 36, is carried out. After the cutting process is completed, the film forming process, in which the organic material layer 40 is formed, is carried out. According to the method for manufacturing in this embodiment, the organic material layer 40 is formed on the side surface 32 of the semiconductor element 22.

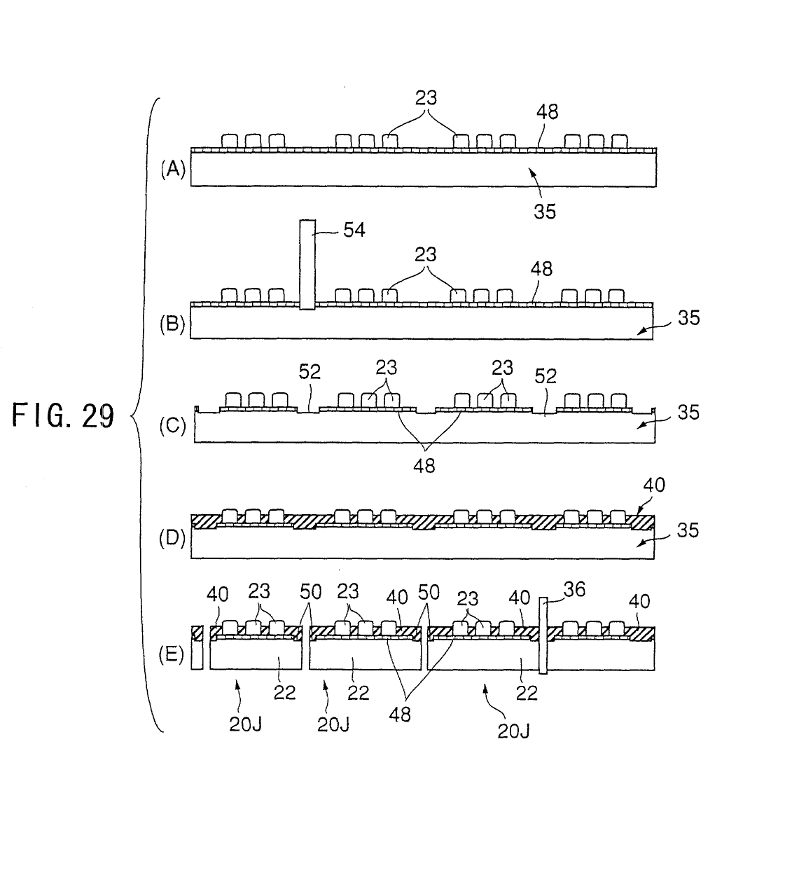

FIG. 29 is a view showing the first deformed example of the method for manufacturing of a semiconductor device 20J shown in FIG. 26. In this deformed example, instead of the laser 51, a grove forming blade 54 is used for removing the contaminant 48 and forming the groove 52 for chamfer.

FIG. 29-(A) shows a semiconductor substrate 35 in a state where the element forming process is completed. The contaminant 48 is removed, and the forming the groove for chamfer process in which the groove 52 for chamfer is formed is carried out. In this embodiment as shown in FIG. 29-(B), the contaminant 48 is removed and the groove 52 for chamfer is formed, by using the grove forming blade 54.

The groove forming blade 54 is set as its blade width is wider than the blade width of the dicing blade 36. The semiconductor substrate 35 is not cut completely by the groove forming blade 54. Rather, the semiconductor substrate 35 is cut by a designated depth of the groove 52 for chamfer. The position, on which a machining process is carried out by the grove forming blade 54, is set as it includes the dicing position where the semiconductor element 22 is cut into pieces of the semiconductor substrate. FIG. 29-(C) shows a state where the groove for chamfer forming process is completed.

After the groove for chamfer forming process is completed, the film forming process, in which the organic material layer 40 is formed on the semiconductor substrate 35 having the groove 52 for chamfer, is carried out as shown in FIG. 29-(D). And then, as shown in FIG. 29 (E), the dicing is carried out on the designated dicing position in the groove 52 for chamfer by the dicing blade 36. Thus, the semiconductor device 20J is formed by the method for manufacturing in this embodiment.

In this embodiment, it is not necessary to use the expensive laser 51. Rather, the groove for chamfer forming process and the cut process are carried out, by the mechanical process in which only the grove forming blade 54 and the dicing blade 36 are used. Hence, it is possible to reduce the cost for manufacturing and processing.

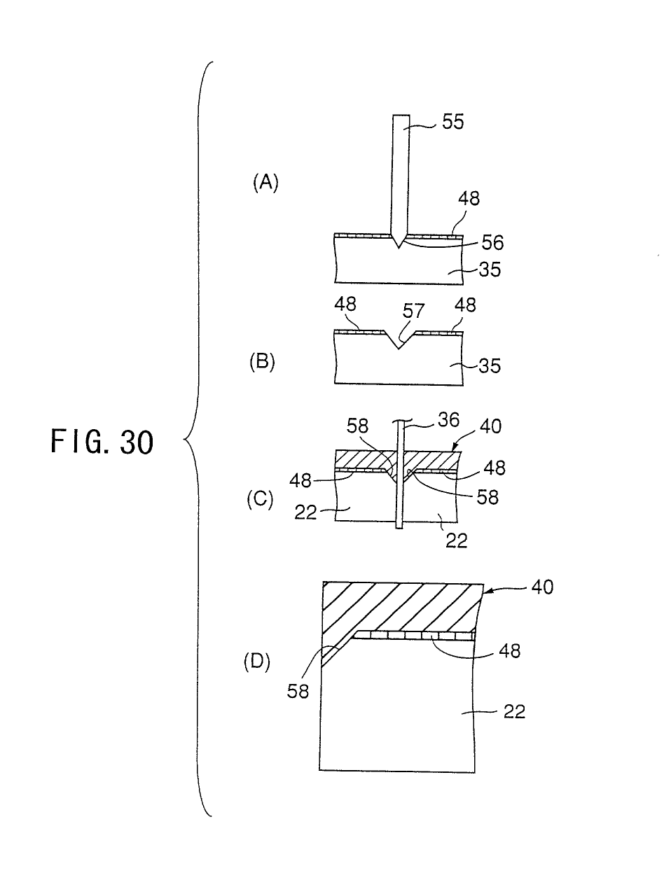

FIG. 30 shows an example in which the groove forming blade 55 having an inclination blade 56 at its end part is used. The groove forming blade 55 having an inclination blade 56 whose section is a triangle form at its end part is used. A triangle groove 57 is formed on the semiconductor substrate 35 by carrying out the groove for chamfer forming process as shown in FIGS. 30-(A) and 30-(B). At this time, the contaminant 48 formed on the semiconductor substrate 35 is removed.

Next, the organic material layer 40 is formed by carrying out the film forming process as shown in FIG. 30-(C). And then, the chamfer part 58 which has inclined faces is formed by the cut process with the dicing blade 36 as shown in FIG. 30-(D). Thus, the form of the chamfer part is not limited to a rectangle but can have any form depending on the form of the end part of the groove forming blade. Hence, a connection area between the organic material layer 40 and the semiconductor element 22, namely the connection strength between the organic material layer 40 and the semiconductor element 22, can be arranged on the basis of the form of the chamfer part.

The respective semiconductor devices 20A to 20J having the CSP structures are explained in the above-mentioned embodiments. However, the present invention is not limited to the semiconductor device having the CSP structures, but it can be applied to a semiconductor device having a wire on a part of interposer. An embodiment, in which the organic material layer 40 is arranged on the semiconductor device having the wire, will be explained.

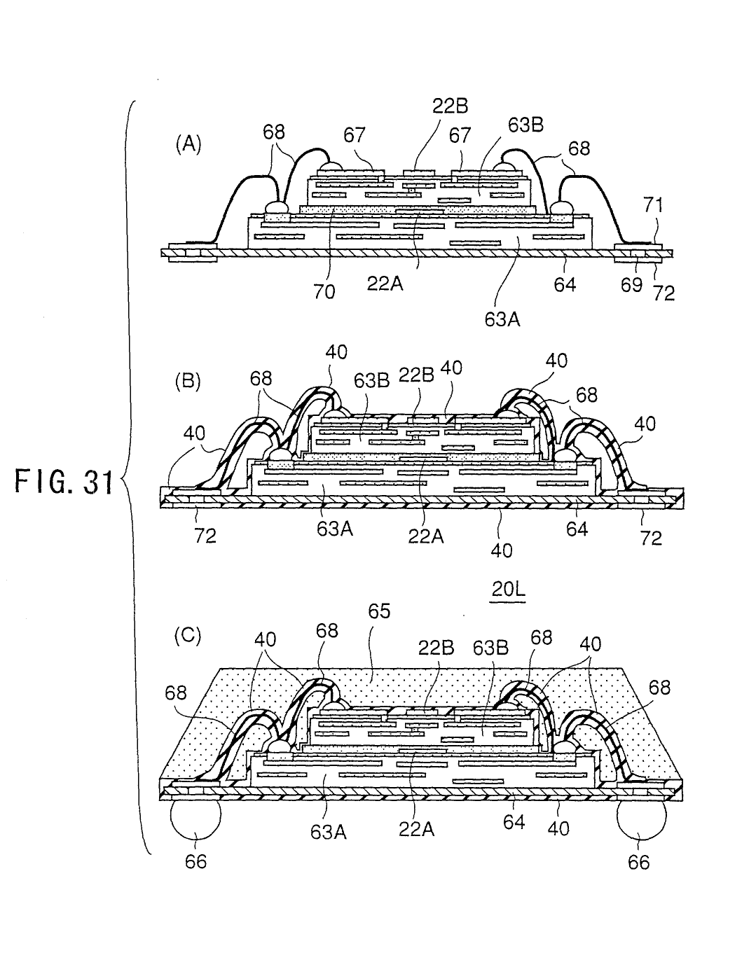

FIG. 31 is a view explaining a semiconductor device 20L and a method for manufacturing of the same according to the eleventh embodiment of the present invention. Referring to FIG. 31-(C), the structure of the semiconductor device 20L will be explained.

The semiconductor device 20L has a multi chip package (MCP) structure in which a plurality of semiconductor elements 22A and 22B are arranged. The semiconductor element 22A is arranged on the upper surface of a multi-layer interconnection board 63A. The semiconductor element 22B is arranged on the upper surface of a multi-layer interconnection board 63B. The multi-layer interconnection board 63A is fixed on the base board 64 by an adhesive which is not shown in FIG. 31. The multi-layer interconnection board 63B is fixed on the multilayer interconnection board 63A by an adhesive 70.

The semiconductor element 22A is connected with a wire 67 formed on the multi-layer interconnection board 63A. Similarly, the semiconductor element 22B is connected with the wire 27 formed on the multi-layer interconnection board 63B. A solder ball 66 as an external connection terminal is arranged on the back surface of the base board 64.

The wire 67 of the multi-layer interconnection board 63A and the wire 67 of the multi-layer interconnection board 63B are connected electrically by the wire 68. Similarly, the wire 67 of the multi-layer interconnection board 63A and the upper part electrode 71 of the multi-layer interconnection board 64 are connected electrically by the wire 68. Also, the upper part electrode 71 on the base board 64 and a lower part electrode 72 on which the solder ball 66 is arranged are connected by a through hole 69. Thus, the respective semiconductor elements 22A and 22B are connected with the solder ball 66 by the wire 68, the wire 67 and the through hole 69. A seal resin 65 is formed for forming the above-mentioned the semiconductor elements 22A and 22B, the multi-layer interconnection boards 63A and 63B, and the wire 68.

As to the wire 68, the wire 68 is covered with the organic material layer 40. The organic material layer 40 is insulating. Therefore, even if a plurality of wires 68 are contacted each other, the wires are not short-circuit each other because of the organic material layer 40. Also, even if the wire 68 is contacted with the multi-layer interconnection boards 63A and 63B, the wire 68 and the multi-layer interconnection boards 63A and 63B are not short.

As shown in FIG. 31-(A), for manufacturing a semiconductor device 20L having the above-mentioned structure, the multi-layer interconnection board 63A is arranged on the base board 64. The semiconductor element 22A is mounted on the multilayer interconnection board 63A. The multi-layer interconnection board 63B is arranged on the multilayer interconnection board 63A. The semiconductor element 22B is mounted on the multi-layer interconnection board 63B. Next, the wire 67 of the multi-layer interconnection board 63B is connected with the wire 67 of the multi-layer interconnection board 63A by the wire 68. The wire 67 of the multilayer interconnection board 63A is connected with the upper part electrode 71 on the base board 64 by the wire 68. FIG. 31-(A) shows a state in which the wire connection process is completed.

After the wire connecting process is completed, a film is arranged on the upper part electrode 72 on the base board 64 for masking. The base board 64 on which the multi-layer interconnection boards 63A and 63B are mounted is provided to the vacuum vapor room 43 as shown in FIG. 6. In the vacuum vapor room 43, the film forming process for forming the organic material layer 40 is carried out.

As described above, the organic material layer 40 is formed all of areas where a vapor phase of the organic material layer is touched. Thus, the film of the organic material layer 40 is formed on the exposed part to the base board 64 and the multilayer interconnection boards 63A and 63B, and the wire 68. FIG. 31-(B) shows a state in which the film forming process is completed.

After the film forming process is completed, the wire 68, on which the film of the organic material layer 40 is formed, is mounted on a mold for molding. The seal process for forming the seal resin 65 is carried out. In the seal process, the wire 68 may be displaced by an injected resin having high pressure in the mold. The more a number of the terminal is increased due to that the semiconductor elements 22A and 22B have high densities, the narrower a pitch between the neighboring wires 68 is. Therefore, the respective wires 68 may touch each other easily.

In this embodiment, the insulating organic material layer 40 is formed on the wire 68 by carrying out the film forming process before the sealing process is carried out. Accordingly, even if wires 68 are contacted each other, the wires are not short-circuit each other. Also, as described above, even if the wire 68 is contacted with the multi-layer interconnection boards 63A and 63B, they are not short-circuit, because the organic material layer 40 is formed on the surfaces of the multilayer interconnection boards 63A and 63B. Accordingly, even if the wire density becomes high, it is possible to keep high reliance of the semiconductor device 20L.

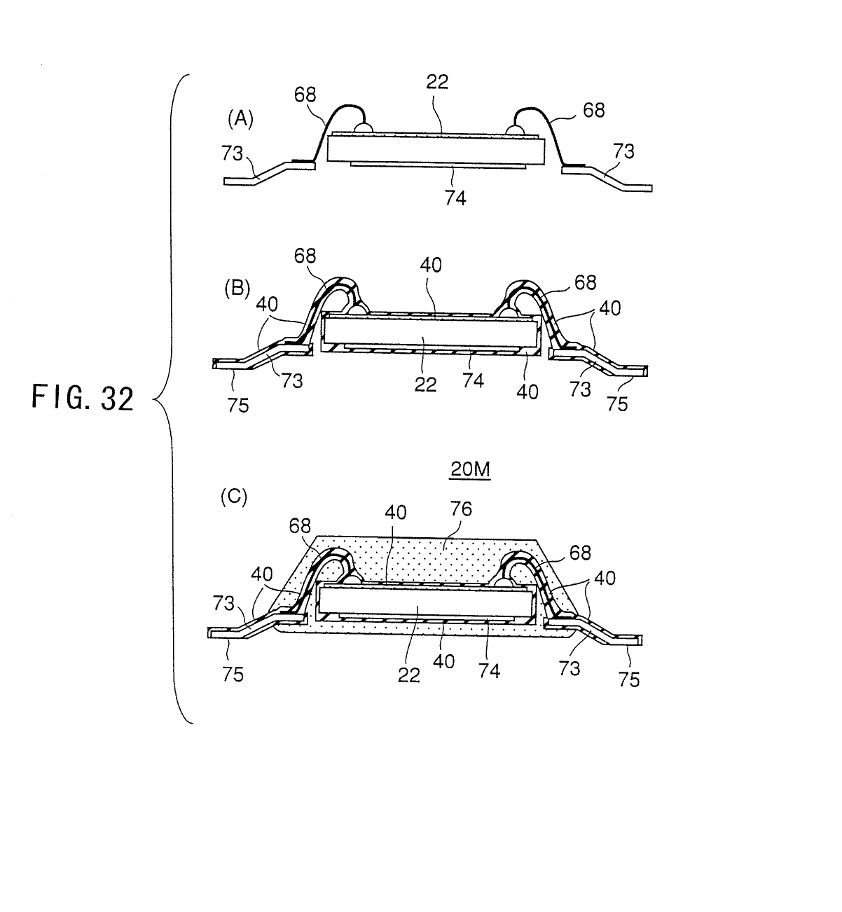

FIG. 32 is a view explaining a semiconductor device 20M and a method for manufacturing of the same, according to the twelfth embodiment of the present invention. Referring to FIG. 32-(C), a structure of the semiconductor device 20M will be explained.

The semiconductor device 20M is a surface connect type having a lead 73. The semiconductor element 22 is fixed on the stage 74 by not shown die bonding material. A wire 68 is arranged between the semiconductor element 22 and an inner lead part of the lead 73, so that the semiconductor element 22 and the lead 73 are connected electrically. Also, a seal resin 76 is formed for sealing the semiconductor element 22, the inner lead part of the lead 73, and the wire 68.

As to the wire 68, the wire 68 is covered with the organic material layer 40. The organic material layer 40 is insulating. Therefore, even if a plurality of wires 68 are contacted each other, the wires are not short-circuit each other because of the organic material layer 40.

As shown in FIG. 32-(A), for manufacturing a semiconductor device 20L having the above-mentioned structure, the semiconductor element 22 is fixed on the stage 74 by using not shown die bonding material. A wire 68 is arranged between the semiconductor element 22 and the inner lead part of the lead 73 by a wire bonding apparatus.

After the wire connecting process is completed, a film is arranged on a place for outside connection in case of the connection of the lead 73 for masking. The semiconductor element 22 and the lead 73 are provided to the vacuum vapor room 43 as shown in FIG. 6. In the vacuum vapor room 43, the film forming process for forming the organic material layer 40 is carried out.

The organic material layer 40 is formed all of areas where a vapor phase of the organic material layer is contacted. Thus, the film of the organic material layer 40 is formed on the semiconductor element 22, the stage 74, the lead 73 other than the exposed part 75, and the wire 68. FIG. 32-(B) shows a state in which the film forming process is completed.

After the film forming process is completed, the semiconductor element 22 and the lead 73 are mounted on a mold for molding. The seal process for forming the seal resin 65 is carried out.

As described above, in the seal process, the resin having high pressure is inserted into the mold. In this embodiment, the insulating organic material layer 40 is formed on the wire 68 in the film forming process, before the sealing process is completed. Therefore, even if the respective wires 68 contact each other, the respective wires 68 are not short-circuit. Hence, even if the wire density is increased, the reliance of the semiconductor device 20L can be kept at a high level.

The present invention is not limited to these embodiments, but various variations and modifications may be made without departing from the scope of the present invention.

This patent application is based on Japanese priority patent application No. 2001-068783 filed on Mar. 12, 2001, the entire contents of which are hereby incorporated by reference.

What is claimed is:

1. A semiconductor device, comprising:
a semiconductor element having a circuit surface on which a projection electrode is formed;
a seal resin which seals the circuit surface of the semiconductor element while exposing at least an end part of the projection electrode;
a connect surface that is to face a board when the semiconductor device is implemented on the board;
a back surface which is opposite to the connect surface;
a side surface situated between the connect surface and the back surface; and
an organic material layer formed on the side surface.

2. The semiconductor device as claimed in claim 1, wherein the organic material layer is further formed on the back surface.

3. The semiconductor device as claimed in claim 1, wherein the organic material layer is further formed on at least part of the connect surface except the end part of the projection electrode.

4. A method of manufacturing a semiconductor device, comprising:
an element forming step of forming a plurality of semiconductor elements on a surface of a semiconductor substrate and forming a projection electrode on the semiconductor elements;
a sealing step of sealing the surface of the semiconductor element with a seal resin while exposing at least an end part of the projection electrode;
a cutting step of cutting the semiconductor substrate into the respective semiconductor elements, each of which constitutes a semiconductor element body; and
a film forming step of forming a film of an organic material in a vapor phase on the semiconductor element body after the cutting process is completed, thereby forming an organic material layer.

5. A semiconductor device, comprising:
a semiconductor element having a circuit surface on which a projection electrode is formed;
a seal resin which seals the circuit surface of the semiconductor element while exposing at least an end part of the projection electrode;
a connect surface that is to face a board when the semiconductor device is implemented on the board;
a back surface which is opposite to the connect surface;
a side surface arranged between the connect surface and the back surface; and
an organic material layer formed on at least one surface of the connect surface and the back surface except the side surface.

6. A method of manufacturing a semiconductor device, comprising:
an element forming step of forming a plurality of semiconductor elements on a surface of a semiconductor substrate and forming a projection electrode on the semiconductor elements;
a sealing step of sealing the surface of the semiconductor element with a seal resin while exposing at least an end part of the projection electrode;
a film forming step of forming a film of an organic material in a vapor phase on the semiconductor element body thereby forming an organic material layer; and
a cutting step of cutting the semiconductor substrate into the respective semiconductor element after the film forming step is completed, each of which constitutes a semiconductor element body.

7. A semiconductor device having a semiconductor element, comprising:
a connect surface on which a projection electrode is formed and which is to face a board when the semiconductor device is implemented on the board;
a back surface which is opposite to the connect surface;
a side surface situated between the connect surface and the back surface; and
an organic material layer formed on at least a part of the connect surface except an end part of the projection electrode.

8. The semiconductor device as claimed in claim 7, wherein the organic material layer is further formed on the side surface.

9. The semiconductor device as claimed in claim 7, wherein the organic material layer is further formed on the back surface.

10. A method of manufacturing a semiconductor device, comprising:
an element forming step of forming a plurality of semiconductor elements on a surface of a semiconductor substrate and forming a projection electrode on the semiconductor elements;
a cutting step of cutting the semiconductor substrate into the respective semiconductor elements, each of which constitutes a semiconductor element body; and
a film forming step of forming a film of an organic material in a vapor phase on the semiconductor element body after the cutting process is completed, thereby forming an organic material layer.

11. A method of manufacturing a semiconductor device, comprising:
an element forming step of forming a plurality of semiconductor elements on a surface of a semiconductor substrate and forming a projection electrode on the semiconductor elements;
a film forming step of forming a film of an organic material in a vapor phase on the semiconductor element body thereby forming an organic material layer; and
a cutting step of cutting the semiconductor substrate into the respective semiconductor element after the film forming step is completed, each of which constitutes a semiconductor element body.

12. A method of manufacturing a semiconductor device, comprising:
an element forming step of forming a plurality of semiconductor elements on a circuit surface of a semiconductor substrate and forming a projection electrode on the semiconductor elements;
a film forming step of forming a film of an organic material in a vapor phase on the semiconductor element body thereby forming an organic material layer on at least a back surface situated at opposite side surface to the circuit surface of the semiconductor substrate;
an element cutting step of remaining the organic material layer and cutting the semiconductor substrate into the respective semiconductor elements after the film forming step is completed;
a test step of conducting a test as to the semiconductor element after the element cutting step is completed; and
an organic material layer cutting step of cutting the organic material layer into respective semiconductor elements after the test process is completed.

13. The semiconductor device as claimed in claim 1, wherein the end part of the projection electrode is projected from the organic material layer.

14. The method of manufacturing a semiconductor device as claimed in claim 6, wherein the organic material layer is formed in a state where a flexible film is pressed to the projection electrode and a part of the end part of the projection electrode is buried in the film, in the film forming step.

15. The semiconductor device as claimed in claim 5, further comprising a chamfer part formed on a border surface of the organic material layer and the semiconductor element.

16. The method of manufacturing a semiconductor device as claimed in claim 6, further comprising a step of forming a groove for a chamfer part on the semiconductor substrate prior to the film forming step and the cutting step are carried out.

17. A semiconductor device, comprising:
a semiconductor element;
an interposer including a wire and connecting the semiconductor device with an external connection terminal;
a seal resin for sealing at least the semiconductor element; and
an organic material layer that covers at least the wire.

18. A method of manufacturing a semiconductor device, comprising:
a wire connecting step of connecting a semiconductor element and an interposer with a wire;
a sealing step of sealing at least the semiconductor element and the wire by a seal resin; and
a film forming step of forming a film of an organic material in a vapor on at least the wire, after the wire connecting step is carried out and before the sealing step is carried out, thereby an forming an organic material layer.
